(19) United States
(12) Patent Application Publication
(10) Pub. No.: US 2026/0190295 A1
(43) Pub. Date: Jul. 2, 2026

(54) DUST AND TEMPERATURE CONTROL IN AN ACTIVE MEMS COOLING SYSTEM

(71) Applicant: Frore Systems Inc., San Jose, CA (US)

(72) Inventors: Sangkyu Kim, San Jose, CA (US); Suryaprakash Ganti, Los Altos, CA (US); Vikram Mukundan, San Ramon, CA (US); Prabhu Sathyamurthy, San Jose, CA (US); Prathima Kapa, Dublin, CA (US); Ji Hoon Kim, Redwood City, CA (US); Philip J. Stephanou, Mountain View, CA (US)

(21) Appl. No.: 19/198,915

(22) Filed: May 5, 2025

Related U.S. Application Data
(63) Continuation-in-part of application No. 18/907,306, filed on Oct. 4, 2024.
Application No. 18/907,306 is a continuation of application No. 17/867,609, filed on Jul. 18, 2022, now Pat. No. 12,137,540.
Application No. 17/867,609 is a continuation of application No. 17/463,417, filed on Aug. 31, 2021, now Pat. No. 11,432,433.
Application No. 17/463,417 is a continuation of application No. 16/915,912, filed on Jun. 29, 2020, now Pat. No. 11,464,140.
(60) Provisional application No. 62/945,001, filed on Dec. 6, 2019.
(60) Provisional application No. 63/643,304, filed on May 6, 2024.
(60) Provisional application No. 63/643,307, filed on May 6, 2024.

(51) Int. Cl. H05K 7/20; B81B 7/00

(52) U.S. Cl. CPC H05K 7/20509; B81B 7/0093

(57) ABSTRACT

The present application discloses a cooling system. The cooling system is configured to modulate temperature of an electronic device. The cooling system comprises a cooling structure and a support structure thermally coupling the cooling structure to a heat-generating structure via thermal conduction. The cooling structure comprises (i) one or more walls defining an inner chamber, (ii) a cooling element, and (iii) a filtration subsystem. The one or more walls comprise one or more inlets, and one or more outlets. The cooling element is configured to drive a fluid from the one or more inlets to the one or more outlets. The filtration subsystem comprises a coarse filter and a fine filter, and the filtration subsystem is configured to remove contaminants introduced by fluid flowing through the one or more inlets.

### CROSS REFERENCE TO OTHER APPLICATIONS

This application claims priority to U.S. Provisional Ser. No. 63/643,304 entitled DUST GUARD FOR MEMS COOLING SYSTEM filed May 6, 2024, and U.S. Provisional Ser. No. 63/643,307 entitled IN SITU THERMISTOR FOR MEMS COOLING SYSTEM filed May 6, 2024, both of which are incorporated herein by reference for all purposes.

This application is a continuation in part of pending U.S. patent application Ser. No. 18/907,306 entitled CENTRALLY ANCHORED MEMS-BASED ACTIVE COOLING SYSTEMS filed Oct. 4, 2024, which is a continuation of U.S. patent application Ser. No. 17/867,609, now U.S. Pat. No. 12,137,540, entitled CENTRALLY ANCHORED MEMS-BASED ACTIVE COOLING SYSTEMS filed Jul. 18, 2022, which is a continuation of U.S. patent application Ser. No. 17/463,417, now U.S. Pat. No. 11,432,433, entitled CENTRALLY ANCHORED MEMS-BASED ACTIVE COOLING SYSTEMS filed Aug. 31, 2021, which is a continuation of U.S. patent application Ser. No. 16/915,912, now U.S. Pat. No. 11,464,140, entitled CENTRALLY ANCHORED MEMS-BASED ACTIVE COOLING SYSTEMS filed Jun. 29, 2020, which claims priority to U.S. Provisional Ser. No. 62/945,001 entitled CENTRALLY ANCHORED MEMS-BASED ACTIVE COOLING SYSTEMS filed Dec. 6, 2019, all of which are incorporated herein by reference for all purposes.

### BACKGROUND OF THE INVENTION

As computing devices grow in speed and computing power, the heat generated by the computing devices also increases. Various mechanisms have been proposed to address the generation of heat. Active devices, such as fans, may be used to drive air through large computing devices, such as laptop computers or desktop computers. Passive cooling devices, such as heat spreaders, may be used in smaller, mobile computing devices, such as smartphones, virtual reality devices and tablet computers. However, such active and passive devices may be unable to adequately cool both mobile devices such as smartphones and larger devices such as laptops and desktop computers. Moreover, incorporating cooling solutions into computing devices may be challenging. Consequently, additional cooling solutions for computing devices are desired.

### BRIEF DESCRIPTION OF THE DRAWINGS

Various embodiments of the invention are disclosed in the following detailed description and the accompanying drawings.

FIGS. 1A-1G depict an embodiment of an active MEMS cooling system including a centrally anchored cooling element.

FIGS. 2A-2B depict an embodiment of an active MEMS cooling system including a centrally anchored cooling element.

FIGS. 3A-3E depict an embodiment of an active MEMS cooling system formed in a tile.

FIGS. 4A-4C depict an embodiment of a filtration system for a MEMS cooling system.

FIGS. 5A-5B depict an embodiment of a filtration system for a MEMS cooling system.

FIG. 5C depicts a relationship between a fine filter inlet area and a drop in fluid flow according to various embodiments.

FIGS. 6A-6B depict an embodiment of a filtration system for a MEMS cooling system.

FIGS. 7A-7B depict an embodiment of a filtration system for a MEMS cooling system.

FIG. 8 depicts a response time for modulating a MEMS cooling system in response to an impulse in a thermal environment of a MEMS cooling system according to various embodiments.

FIGS. 9A-9I depict an embodiment of module including a tile and a hood during fabrication.

FIG. 10 depicts a relationship between temperature collected by a thermistor configured on a MEMS cooling system and thermal performance of a module associated with the MEMS cooling system.

FIG. 11 depicts an embodiment of a method for using an active cooling mems system.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Various embodiments provide a cooling system. The cooling system is configured to modulate temperature of an electronic device. The cooling system comprises a cooling structure and a support structure thermally coupling the cooling structure to a heat-generating structure via thermal conduction. The cooling structure comprises (i) one or more walls defining an inner chamber, (ii) a cooling element, and (iii) a filtration subsystem. The one or more walls comprise one or more inlets, and one or more outlets. The cooling element is configured to drive a fluid from the one or more inlets to the one or more outlets. The filtration subsystem comprises a coarse filter and a fine filter, and the filtration subsystem is configured to remove contaminants introduced by fluid flowing through the one or more inlets.

Various embodiments provide a cooling system. The cooling system is configured to modulate temperature of an electronic device. The cooling system comprises a cooling structure and a support structure thermally coupling the cooling structure to a heat-generating structure via thermal conduction. The cooling structure comprises a cooling element and a thermistor. The cooling element is configured to cool a heat-generating structure via thermal conduction. The thermistor is configured to measure a temperature associated with the cooling element. The cooling element is actuated based at least in part on the temperature. In some embodiments, an operating voltage for power used to drive the cooling element is modulated based on temperature data collected by the thermistor. In some embodiments, an operating voltage for power used to drive the cooling element is modulated to maintain the temperature associated with the cooling element at a predefined temperature.

As computing devices continue to increase in performance and decrease in size, managing thermal conditions within these devices has become increasingly challenging. Higher processor speeds, denser electronic components, and more compact device footprints result in elevated thermal outputs that conventional cooling systems struggle to manage effectively. Active cooling systems utilizing micro-electro-mechanical systems (MEMS) have emerged as effective solutions, especially for compact and mobile electronic devices such as smartphones, tablets, laptops, augmented reality (AR), and virtual reality (VR) headsets. MEMS cooling systems typically use vibrational elements or actuators to drive a cooling fluid, such as air, through internal chambers and toward heat-generating components.

However, the integration of such MEMS cooling systems presents unique challenges. Specifically, MEMS cooling systems draw air directly from the ambient environment, exposing internal device components to potential contamination from particulates such as dust, lint, pollen, and other airborne contaminants. Such particulates can accumulate within cooling structures, significantly reducing cooling efficiency, impairing device performance, and ultimately shortening the operational lifespan of electronic components. Although traditional filtration methods may reduce contaminants, they can introduce undesirable airflow restrictions, leading to increased power consumption, reduced cooling effectiveness, and undesirable acoustic noise.

Various embodiments provide a cooling system for modulating the temperature of electronic devices while effectively mitigating contamination from airborne particulates. The cooling system comprises a MEMS cooling structure coupled via a support structure to one or more heat-generating components. The MEMS cooling structure utilizes an actuator or cooling element configured to vibrate at resonant frequencies to drive airflow through one or more inlets and out through corresponding outlets, thereby dissipating heat from the heat-generating components.

In some embodiments, the MEMS cooling structure integrates a filtration subsystem configured to substantially reduce contaminants entering through the air inlet. The filtration subsystem comprises a dual-filter arrangement, including a coarse pre-filter and a fine main filter. In particular, the coarse filter may be a low-pressure-drop hydrophobic mesh, such as a Saatifil filter, that functions as an initial barrier against larger contaminants, water droplets, and spills. The fine filter may be a high-efficiency particulate filter, such as a MERV 14 filter, configured to trap finer contaminants effectively. The coarse filter is strategically positioned upstream of the fine filter to ensure that the incoming air velocity and pressure drop at the fine filter are reduced, thereby significantly minimizing airflow impedance and preserving cooling performance.

In some embodiments, a filter gap or spacing is maintained between the coarse filter and the fine filter to allow diffusion of airflow and further reduce the pressure drop across the fine filter. The filtration subsystem may be designed as a modular or replaceable component, allowing users to conveniently replace the filters when necessary, thereby maintaining consistent cooling performance and extending device longevity. In some embodiments, the filtration subsystem is configured for the fine filter and the coarse filter to be replaceable.

By implementing a dual-filter configuration with optimized spacing, various embodiments improve the cleanliness and reliability of MEMS cooling systems, enhancing thermal management efficiency and device performance while minimizing power consumption and acoustic impact, and ultimately, extending the operating lifetime of the cooling system.

Additionally, electronic devices continue to become smaller and more powerful, resulting in increased thermal output from integrated circuits and other heat-generating components. Effective thermal management is particularly critical in compact electronic devices such as smartphones, tablets, laptops, wearables, and virtual or augmented reality devices, where space constraints severely limit the effectiveness of conventional cooling methods. Active cooling solutions utilizing MEMS have been introduced to efficiently dissipate heat in these constrained environments. MEMS cooling systems commonly employ vibrating actuators that drive fluid flow, typically air, over heat-generating structures to remove excess heat and maintain optimal device temperatures.

However, optimal performance of MEMS cooling systems depends significantly on controlling the resonant vibrational frequency and amplitude of their cooling elements. Because resonant frequency is sensitive to changes in the temperature of the cooling element, variations in operating temperature can lead to suboptimal performance. Specifically, fluctuations in temperature may shift the cooling element away from its ideal resonant frequency, reducing cooling efficiency, increasing power consumption, and negatively affecting device performance and user experience. Traditional thermal management solutions often rely on separate controllers, such as central processing units or system-on-chip modules, to regulate cooling, which can add complexity, latency, and cost.

Various embodiments provide a system that efficiently maintains the resonant frequency and optimal thermal performance of the cooling element by directly monitoring and controlling the temperature of the cooling element itself (or a temperature that serves as a proxy for the cooling element itself).

Various embodiments provide a MEMS cooling system that integrates temperature sensing directly into the cooling element to actively control and maintain its operating temperature within a predefined, relatively narrow range. The system includes a cooling structure having one or more cooling elements configured to dissipate heat from an electronic device, and a thermistor or other suitable temperature sensor thermally coupled to or embedded in at least one of these cooling elements.

In various embodiments, the thermistor continuously measures the temperature of the cooling element in real-time. The measured temperature is used to dynamically adjust the operating voltage and/or power supplied to the cooling element, thereby modulating its amplitude of vibration and consequently its cooling performance. By adjusting the voltage or power applied to the cooling element based on feedback from the thermistor, the system maintains the cooling element temperature within a narrow, predefined temperature range, effectively stabilizing the resonant frequency of the cooling element.

In some embodiments, the control scheme includes increasing operating voltage and power when the measured temperature indicates that the cooling element is above the predefined optimal temperature, thereby increasing cooling capacity. For example, the airflow and cooling efficiency may be improved. Conversely, if the thermistor detects a cooling element temperature below the predefined optimal temperature, the operating voltage and power may be reduced accordingly. In this manner, resonant frequency variations due to temperature fluctuations are minimized, maximizing cooling performance, improving device reliability, and enhancing user experience.

Additionally, embodiments described herein enable real-time temperature monitoring and rapid control response (on the order of milliseconds), allowing quick/real-time detection by the thermistor. The system can then implement adjustments to the cooling element operation based on the temperature detection by the thermistor. This rapid feedback loop improves overall thermal management efficiency, reduces power consumption, and extends the operating life of electronic devices in which the MEMS cooling system is utilized. Furthermore, by directly integrating thermal sensing and control within the MEMS cooling structure, external controllers, additional hardware complexity, and associated costs can be reduced or eliminated, providing significant performance and integration advantages.

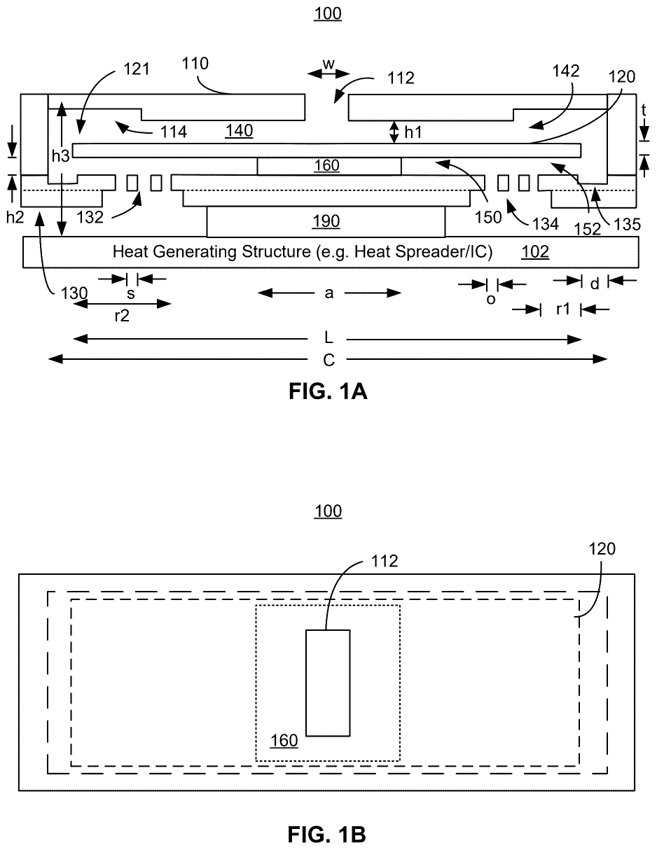

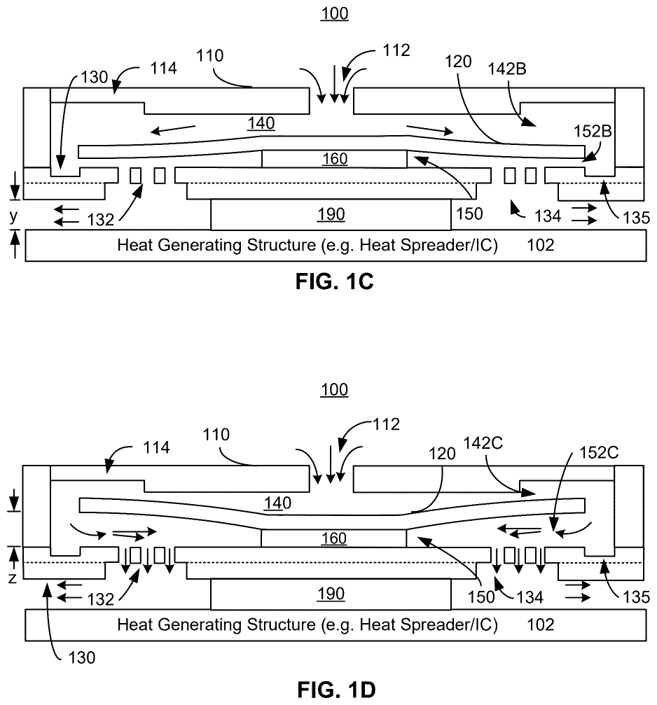

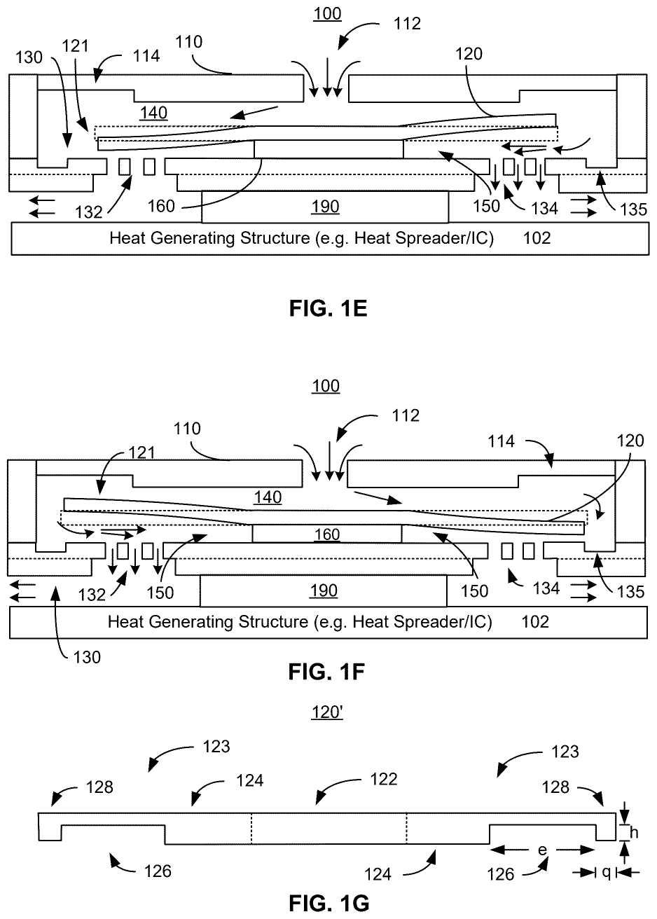

FIGS. 1A-1G are diagrams depicting an exemplary embodiment of active MEMS cooling system 100 usable with heat-generating structure 102 and including a centrally anchored cooling element 120 or 120′. Although termed a cooling system, MEMS system 100 and analogous systems described herein may be considered heat transfer systems and/or fluid transfer systems. Cooling element 120 is shown in FIGS. 1A-1F and cooling element 120′ is shown in FIG. 1G. For clarity, only certain components are shown. FIGS. 1A-1G are not to scale. FIGS. 1A and 1B depict cross-sectional and top views of cooling system 100 in a neutral position. FIGS. 1C-1D depict cooling system 100 during actuation for in-phase vibrational motion. FIGS. 1E-1F depict cooling system 100 during actuation for out-of-phase vibrational motion. Although shown as symmetric, cooling system 100 need not be.

Cooling system 100 includes top plate 110 having vent 112 and cavities 114 therein, cooling element 120, orifice plate 130 having orifices 132 and cavities 134 and 135 therein, support structure (or “anchor”) 160 and chambers 140 and 150 (collectively chamber 140/150) formed therein. Cooling element 120 is supported at its central region by anchor 160. Although termed a cooling element with respect to FIGS. 1A-1G, cooling element 120 and analogous elements described herein may also be considered actuators, vibrating elements, vibrating components, active components, active elements, and/or other terms indicating that the element is configured to undergo vibrational motion when activated (or energized) and/or to drive fluid through a system. Regions of cooling element 120 closer to and including portions of the cooling element's perimeter (e.g. tip 121) vibrate when actuated. In some embodiments, tip 121 of cooling element 120 includes a portion of the perimeter furthest from anchor 160 and undergoes the largest deflection during actuation of cooling element 120. For clarity, only one tip 121 of cooling element 120 is labeled in FIG. 1A. In some embodiments, vibration of portions of cooling element 120 may cause motion (e.g. rotation) of anchor 160. Also shown is pedestal 190 that connects orifice plate 130 to and offsets orifice plate 130 from heat-generating structure 102. In some embodiments, pedestal 190 also thermally couples orifice plate 130 to heat-generating structure 102. In some embodiments, orifice plate 130 may include an upper plate and a lower, jet channel plate. This is indicated by the dashed line in orifice plate 130. Thus, multiple plates and/or plate(s) having various structures may be used at the bottom plate for cooling system 100.

FIG. 1A depicts cooling system 100 in a neutral position. Thus, cooling element 120 is shown as substantially flat. For in-phase operation, cooling element 120 is driven to vibrate between positions shown in FIGS. 1C and 1D. This vibrational motion draws fluid (e.g. air) into vent 112, through chambers 140 and 150 and out orifices 132 at high speed and/or flow rates. The geometry of cooling system 100 may be configured to achieve particular speeds and/or flow rates may for various applications and fluids. For example, the speed at which the fluid (e.g., air) is driven toward heat-generating structure 102 may be at least ten meters per second. In some embodiments, the flow rate through cooling system 100 may be up to approximately 0.08 cubic feet per minute (e.g., at least 0.04 or 0.05 and not more than 0.08 cfm) for air. In some embodiments, the flow rate through cooling system 100 may be up to approximately 0.08 cubic feet per minute per cell. In some embodiments, the flow rate through cooling system 100 may be up to approximately 0.3 cubic feet per minute per system comprising four cells. In some embodiments, the speed may be at least thirty meters per second (e.g. exiting orifices 132 or through the small gap 152B). In some embodiments, the fluid is driven by cooling element 120 toward heat-generating structure 102 at a speed of at least forty-five meters per second. In some embodiments, the fluid is driven toward heat-generating structure 102 by cooling element 120 at speeds of at least sixty meters per second. Other speeds may be possible in some embodiments. Cooling system 100 is also configured so that little or no fluid is drawn back into chamber 140/150 through orifices 132 by the vibrational motion of cooling element 120.

Heat-generating structure 102 is desired to be cooled by cooling system 100. In some embodiments, heat-generating structure 102 generates heat. For example, heat-generating structure may be an integrated circuit. In some embodiments, heat-generating structure 102 is desired to be cooled but does not generate heat itself. Heat-generating structure 102 may conduct heat (e.g. from a nearby object that generates heat). For example, heat-generating structure 102 might be a heat spreader or a vapor chamber. Thus, heat-generating structure 102 may include semiconductor component(s) including individual integrated circuit components such as processors, other integrated circuit(s) and/or chip package(s); sensor(s); optical device(s); one or more batteries; other component(s) of an electronic device such as a computing device; heat spreaders; heat pipes; other electronic component(s) and/or other device(s) desired to be cooled. In some embodiments, heat-generating structure 102 may be a thermally conductive part of a module containing cooling system 100. For example, cooling system 100 may be affixed to heat-generating structure 102, which may be coupled to another heat spreader, a heatsink, vapor chamber, integrated circuit, or other separate structure desired to be cooled.

The devices in which cooling system 100 is desired to be used may also have limited space in which to place a cooling system. For example, cooling system 100 may be used in computing devices. Such computing devices may include but are not limited to smartphones, tablet computers, laptop computers, tablets, two-in-one laptops, hand held gaming systems, digital cameras, virtual reality headsets, augmented reality headsets, mixed reality headsets and other devices that are thin. Cooling system 100 may be a micro-electro-mechanical system (MEMS) cooling system capable of residing within mobile computing devices and/or other devices having limited space in at least one dimension. For example, the total height, h3, of cooling system 100 (from the top of heat-generating structure 102 to the top of top plate 110) may be less than 2 millimeters. In some embodiments, the total height of cooling system 100 is not more than 1.5 millimeters. In some embodiments, this total height is not more than 1.1 millimeters. In some embodiments, the total height does not exceed one millimeter. In some embodiments, the total height does not exceed two hundred and fifty micrometers. Similarly, the distance between the bottom of orifice plate 130 and the top of heat-generating structure 102, y, may be small. In some embodiments, y is at least two hundred micrometers and not more than 1.2 millimeters. For example, y may be at least two hundred and fifty micrometers and not more than three hundred micrometers. In some embodiments, y is at least five hundred micrometers and not more than one millimeter. In some embodiments, y is at least two hundred micrometers and not more than three hundred micrometers. Thus, cooling system 100 is usable in computing devices and/or other devices having limited space in at least one dimension. However, nothing prevents the use of cooling system 100 in devices having fewer limitations on space and/or for purposes other than cooling. Although one cooling system 100 is shown (e.g. one cooling cell), multiple cooling systems 100 might be used in connection with heat-generating structure 102. For example, a one or two-dimensional array of cooling cells might be utilized.

Cooling system 100 is in communication with a fluid used to cool heat-generating structure 102. The fluid may be a gas and/or a liquid. For example, the fluid may be air, air combined with liquid vapor, or a liquid. In some embodiments, the fluid includes fluid from outside of the device in which cooling system 100 resides (e.g. provided through external vents in the device). In some embodiments, the fluid circulates within the device in which cooling system 100 resides (e.g. in an enclosed device).

Cooling element 120 can be considered to divide the interior of active MEMS cooling system 100 into top chamber 140 and bottom chamber 150. Top chamber 140 is formed by cooling element 120, the sides, and top plate 110. Bottom chamber 150 is formed by orifice plate 130, the sides, cooling element 120 and anchor 160. Top chamber 140 and bottom chamber 150 are connected at the periphery of cooling element 120 and together form chamber 140/150 (e.g. an interior chamber of cooling system 100).

The size and configuration of top chamber 140 may be a function of the cell (cooling system 100) dimensions, cooling element 120 motion, and the frequency of operation. Top chamber 140 has a height, h1. The height of top chamber 140 may be selected to provide sufficient pressure to drive the fluid to bottom chamber 150 and through orifices 132 at the desired flow rate and/or speed. Top chamber 140 is also sufficiently tall that cooling element 120 does not contact top plate 110 when actuated. The magnitude of the deflection of cooling element 120 may also be tailored by, for example, changing the driving voltage of the signal used to drive vibration of cooling element 120. In some embodiments, the height of top chamber 140 is at least fifty micrometers and not more than five hundred micrometers. In some embodiments, top chamber 140 has a height of at least two hundred and not more than three hundred micrometers.

Bottom chamber 150 has a height, h2. In some embodiments, the height of bottom chamber 150 is sufficient to accommodate the motion of cooling element 120. For example, the height of bottom chamber 150 may be sufficiently large to accommodate the maximum amplitude of vibration of cooling element 120. Thus, no portion of cooling element 120 contacts orifice plate 130 during normal operation in some embodiments. Bottom chamber 150 is generally smaller than top chamber 140 and may aid in reducing the backflow of fluid into orifices 132. In some embodiments, the height of bottom chamber 150 is the maximum deflection of cooling element 120 plus at least five micrometers and not more than ten micrometers. In some embodiments, the deflection of cooling element 120 (e.g. the deflection of tip 121), z, has an amplitude of at least ten micrometers and not more than one hundred micrometers. In some such embodiments, the amplitude of deflection of cooling element 120 is at least ten micrometers and not more than sixty micrometers. However, the amplitude of deflection of cooling element 120 depends on factors such as the desired flow rate through cooling system 100 and the configuration of cooling system 100. Thus, the height of bottom chamber 150 generally depends on the flow rate through and other components of cooling system 100.

Top plate 110 includes vent 112 through which fluid may be drawn into cooling system 100. Top vent 112 may have a size chosen based on the desired acoustic pressure in chamber 140. For example, in some embodiments, the width, w, of vent 112 is at least five hundred micrometers and not more than one thousand micrometers. In some embodiments, the width of vent 112 is at least two hundred fifty micrometers and not more than two thousand micrometers. In the embodiment shown, vent 112 is a centrally located aperture in top plate 110. In other embodiments, vent 112 may be located elsewhere. For example, vent 112 may be closer to one of the edges of top plate 110. Vent 112 may have a circular, rectangular or other shaped footprint. Although a single vent 112 is shown, multiple vents might be used. For example, vents may be offset toward the edges of top chamber 140 or be located on the side(s) of top chamber 140. Top plate 110 also includes cavities 114 therein. Cavities 114 may facilitate vibration of cooling element 120 by moderating the pressure variation near tip of cooling element 120. In other embodiments, cavities 114 may be omitted and top plate 110 may be substantially flat. In some embodiments, other and/or additional trenches and/or other structures may be provided in top plate 110 to modify the configuration of top chamber 140 and/or the region above top plate 110.

Anchor (support structure) 160 supports cooling element 120 at the central portion of cooling element 120. Thus, at least part of the perimeter of cooling element 120 is unpinned and free to vibrate. In some embodiments, anchor 160 extends along a central axis of cooling element 120 (e.g. perpendicular to the page in FIGS. 1A and 1C-1F). In such embodiments, portions of cooling element 120 that vibrate (e.g. including tip 121) move in a cantilevered fashion. Thus, portions of cooling element 120 may move in a manner analogous to the wings of a butterfly (i.e. in phase) and/or analogous to a see-saw (i.e. out of phase). Thus, the portions of cooling element 120 that vibrate in a cantilevered fashion do so in phase in some embodiments and out of phase in other embodiments. In some embodiments, anchor 160 does not extend along an axis of cooling element 120. In such embodiments, all portions of the perimeter of cooling element 120 are free to vibrate (e.g. analogous to a jellyfish). In the embodiment shown, anchor 160 supports cooling element 120 from the bottom of cooling element 120. In other embodiments, anchor 160 may support cooling element 120 in another manner. For example, anchor 160 may support cooling element 120 from the top (e.g. cooling element 120 hangs from anchor 160). In some embodiments, the width, a, of anchor 160 is at least 0.5 millimeters and not more than four millimeters. In some embodiments, the width of anchor 160 is at least two millimeters and not more than 2.5 millimeters. Anchor 160 may occupy at least ten percent and not more than fifty percent of cooling element 120.

Cooling element 120 has a first side distal from heat-generating structure 102 and a second side proximate to heat-generating structure 102. In the embodiment shown in FIGS. 1A and 1C-1F, the first side of cooling element 120 is the top of cooling element 120 (closer to top plate 110) and the second side is the bottom of cooling element 120 (closer to orifice plate 130). Cooling element 120 is actuated to undergo vibrational motion as shown in FIGS. 1A and 1C-1F. The vibrational motion of cooling element 120 drives fluid from the first side of cooling element 120 distal from heat-generating structure 102 (e.g. from top chamber 140) to a second side of cooling element 120 proximate to heat-generating structure 102 (e.g. to bottom chamber 150). The vibrational motion of cooling element 120 also draws fluid through vent 112 and into top chamber 140; forces fluid from top chamber 140 to bottom chamber 150; and drives fluid from bottom chamber 150 through orifices 132 of orifice plate 130. Thus, cooling element 120 may be viewed as an actuator. Although described in the context of a single, continuous cooling element, in some embodiments, cooling element 120 may be formed by two (or more) cooling elements. Each of the cooling elements is depicted as one portion pinned (e.g. supported by support structure 160) and an opposite portion unpinned. Thus, a single, centrally supported cooling element 120 may be formed by a combination of multiple cooling elements supported at an edge.

Cooling element 120 has a length, L, that depends upon the frequency at which cooling element 120 is desired to vibrate. In some embodiments, the length of cooling element 120 is at least four millimeters and not more than ten millimeters. In some such embodiments, cooling element 120 has a length of at least six millimeters and not more than eight millimeters. The depth of cooling element 120 (e.g. perpendicular to the plane shown in FIGS. 1A and 1C-1F) may vary from one fourth of L through twice L. For example, cooling element 120 may have the same depth as length. The thickness, t, of cooling element 120 may vary based upon the configuration of cooling element 120 and/or the frequency at which cooling element 120 is desired to be actuated. In some embodiments, the cooling element thickness is at least two hundred micrometers and not more than three hundred and fifty micrometers for cooling element 120 having a length of eight millimeters and driven at a frequency of at least twenty kilohertz and not more than twenty-five kilohertz. The length, C, of chamber 140/150 is close to the length, L, of cooling element 120. For example, in some embodiments, the distance, d, between the edge of cooling element 120 and the wall of chamber 140/150 is at least one hundred micrometers and not more than five hundred micrometers. In some embodiments, d is at least two hundred micrometers and not more than three hundred micrometers.

Cooling element 120 may be driven at a frequency that is at or near both the resonant frequency for an acoustic resonance of a pressure wave of the fluid in top chamber 140 and the resonant frequency for a structural resonance of cooling element 120. The portion of cooling element 120 undergoing vibrational motion is driven at or near resonance (the “structural resonance”) of cooling element 120. This portion of cooling element 120 undergoing vibration may be a cantilevered section. The frequency of vibration for structural resonance is termed the structural resonant frequency. Use of the structural resonant frequency in driving cooling element 120 reduces the power consumption of cooling system 100. Cooling element 120 and top chamber 140 may also be configured such that this structural resonant frequency corresponds to a resonance in a pressure wave in the fluid being driven through top chamber 140 (the acoustic resonance of top chamber 140). The frequency of such a pressure wave is termed the acoustic resonant frequency. At acoustic resonance, a node in pressure occurs near vent 112 and an antinode in pressure occurs near the periphery of cooling system 100 (e.g. near tip 121 of cooling element 120 and near the connection between top chamber 140 and bottom chamber 150). The distance between these two regions is C/2. Thus, C/2=nλ/4, where λ is the acoustic wavelength for the fluid and n is odd (e.g. n=1, 3, 5, etc.). For the lowest order mode, C=λ/2. Because the length of chamber 140 (e.g. C) is close to the length of cooling element 120, in some embodiments, it is also approximately true that L/2=nλ/4, where λ is the acoustic wavelength for the fluid and n is odd. Thus, the frequency at which cooling element 120 is driven, ν, is at or near the structural resonant frequency for cooling element 120. The frequency n is also at or near the acoustic resonant frequency for at least top chamber 140. The acoustic resonant frequency of top chamber 140 generally varies less dramatically with parameters such as temperature and size than the structural resonant frequency of cooling element 120. Consequently, in some embodiments, cooling element 120 may be driven at (or closer to) a structural resonant frequency rather than to the acoustic resonant frequency.

Orifice plate 130 has orifices 132 and cavities 134 and 135 therein. Although a particular number and distribution of orifices 132 and cavities 134 and 135 are shown, another number and/or another distribution may be used. Cavities 134 and/or 135 may be configured differently or may be omitted. In some embodiments, other cavities may be within flow chamber 140/150 or the jet channel between orifice plate 130 and heat-generating structure 102. Cavity 135 may assist in capturing dust entering flow chamber 140/150 and/or may enhance fluid flow. A single orifice plate 130 is used for a single cooling system 100. In other embodiments, multiple cooling systems 100 may share an orifice plate. For example, multiple cells 100 may be provided together in a desired configuration. In such embodiments, the cells 100 may be the same size and configuration or different size(s) and/or configuration(s). Orifices 132 are shown as having an axis oriented normal to a surface of heat-generating structure 102. In other embodiments, the axis of one or more orifices 132 may be at another angle. For example, the angle of the axis may be from substantially zero degrees through a nonzero acute angle from normal to the surface. Orifices 132 also have sidewalls that are substantially parallel to the normal to the surface of orifice plate 130. In some embodiments, orifices may have sidewalls at a nonzero angle to the normal to the surface of orifice plate 130. For example, orifices 132 may be cone-shaped. Further, although orifice place 130 is shown as having a particular configuration, other configurations are possible.

The size, number, distribution, and locations of orifices 132 are chosen to control the flow rate of fluid driven to the surface of heat-generating structure 102. The locations and configurations of orifices 132 may be configured to increase the fluid flow from bottom chamber 150 through orifices 132 to the jet channel (the region between the bottom of orifice plate 130 and the top of heat-generating structure 102). The locations and configurations of orifices 132 may also be selected to reduce the suction flow (e.g. back flow) from the jet channel through orifices 132. In some embodiments, the ratio of the flow rate from top chamber 140 into bottom chamber 150 to the flow rate from the jet channel through orifices 132 (the “net flow ratio”) is greater than 2:1. In some embodiments, the net flow ratio is at least 85:15. In some embodiments, the net flow ratio is at least 90:10. In order to provide the desired pressure, flow rate, suction, and net flow ratio, orifices 132 may be desired to be at least a distance, r1, from tip 121 and not more than a distance, r2, from tip 121 of cooling element 120. In some embodiments, r1 is at least one hundred micrometers (e.g. r1≥100 μm) and r2 is not more than one millimeter (e.g. r2≤1000 μm). In some embodiments, orifices 132 are at least two hundred micrometers from tip 121 of cooling element 120 (e.g. r1≥200 μm). In some such embodiments, orifices 132 are at least three hundred micrometers from tip 121 of cooling element 120 (e.g. r1≥300 μm). In some embodiments, orifices 132 have a width, o, of at least one hundred micrometers and not more than five hundred micrometers. In some embodiments, orifices 132 have a width of at least two hundred micrometers and not more than three hundred micrometers. In some embodiments, the orifice separation, s, is at least one hundred micrometers and not more than one millimeter. In some such embodiments, the orifice separation is at least four hundred micrometers and not more than six hundred micrometers. In some embodiments, orifices 132 are also desired to occupy a particular fraction of the area of orifice plate 130. For example, orifices 132 may cover at least five percent and not more than fifteen percent of the footprint of orifice plate 130 in order to achieve a desired flow rate of fluid through orifices 132. In some embodiments, orifices 132 cover at least eight percent and not more than twelve percent of the footprint of orifice plate 130.

In some embodiments, cooling element 120 is actuated using a piezoelectric material. Cooling element 120 may be driven by a piezoelectric material that is mounted on or integrated into cooling element 120. In some embodiments, cooling element 120 is driven in another manner including but not limited to providing a piezoelectric material on another structure in cooling system 100. Cooling element 120 and analogous cooling elements are referred to hereinafter as piezoelectric cooling elements though it is possible that a mechanism other than a piezoelectric material might be used to drive the cooling element. In some embodiments, cooling element 120 includes a piezoelectric layer on substrate. The substrate may include or consist of stainless steel, a Ni alloy, Hastelloy, Al (e.g. an Al alloy), and/or Ti (e.g. a Ti alloy such as Ti6Al-4V). In some embodiments, a piezoelectric layer includes multiple sublayers formed as thin films on the substrate. In other embodiments, the piezoelectric layer may be a bulk layer affixed to the substrate. Such a piezoelectric cooling element 120 also includes electrodes used to activate the piezoelectric material. The substrate functions as an electrode in some embodiments. In other embodiments, a bottom electrode may be provided between the substrate and the piezoelectric layer. Other layers including but not limited to seed, capping, passivation, or other layers might be included in the piezoelectric cooling element. Thus, cooling element 120 may be actuated using a piezoelectric material.

In some embodiments, cooling system 100 includes chimneys (not shown) and/or other ducting. Such ducting provides a path for heated fluid to flow away from heat-generating structure 102. In some embodiments, ducting returns fluid to the side of top plate 110 distal from heat-generating structure 102. In some embodiments, ducting may instead direct fluid away from heat-generating structure 102. Thus, the fluid is allowed to carry away heat from heat-generating structure 102.

Operation of cooling system 100 is described in the context of FIGS. 1A and 1C-1F. Although described in the context of particular pressures, gap sizes, and timing of flow, operation of cooling system 100 is not dependent upon the explanation herein. FIGS. 1C-1D depict in-phase operation of cooling system 100. Referring to FIG. 1C, cooling element 120 has been actuated so that its tip 121 moves away from top plate 110. FIG. 1C can thus be considered to depict the end of a down stroke of cooling element 120. Because of the vibrational motion of cooling element 120, gap 152 for bottom chamber 150 has decreased in size and is shown as gap 152B. Conversely, gap 142 for top chamber 140 has increased in size and is shown as gap 142B. Because top chamber 140 increases in size, a lower pressure is present in top chamber 140. Because bottom chamber 150 has decreased in size, a higher pressure is present at gap 152B.

Cooling element 120 is also actuated so that tip 121 moves away from heat-generating structure 102 and toward top plate 110. FIG. 1D can thus be considered to depict the end of an up stroke of cooling element 120. Because of the motion of cooling element 120, gap 142 has decreased in size and is shown as gap 142C. Gap 152 has increased in size and is shown as gap 152C. Thus, a higher pressure is present near gap 142C, while a lower pressure is present near gap 152C. The net motion of fluid through chamber 140/150 is indicated in FIGS. 1C and 1D by unlabeled arrows. However, the unlabeled arrows in FIGS. 1C and 1D are not intended to indicate the motion of fluid at a particular time. Thus, cooling system 100 is able to drive fluid from top chamber 140 to bottom chamber 150 without an undue amount of backflow of heated fluid from the jet channel entering bottom chamber 150. Moreover, cooling system 100 may operate such that fluid is drawn in through vent 112 and driven out through orifices 132 without cooling element 120 contacting top plate 110 or orifice plate 130. Thus, pressures are developed within chambers 140 and 150 that effectively open and close vent 112 (e.g., by pressures near gap 142/142B/142C) and orifices 132 (e.g. by pressures near gap 152/152B/152C) such that fluid is driven through cooling system 100 as described herein.

The motion between the positions shown in FIGS. 1C and 1D is repeated. Thus, cooling element 120 undergoes vibrational motion indicated in FIGS. 1A-1D, drawing fluid through vent 112 from the distal side of top plate 110 into top chamber 140; transferring fluid from top chamber 140 to bottom chamber 150; and pushing the fluid through orifices 132 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at frequencies from 15 kHz through 30 kHz. In some embodiments, cooling element 120 vibrates at a frequency/frequencies of at least 20 kHz and not more than 30 kHz. In some embodiments, cooling element vibrates at a frequency of at least 23 kHz and not more than 26 kHz. The structural resonant frequency of cooling element 120 is within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 may move substantially normal (perpendicular) to the top surface of heat-generating structure 102. In some embodiments, the fluid motion may have a nonzero acute angle with respect to the normal to the top surface of heat-generating structure 102. In either case, the fluid may thin and/or form apertures in the boundary layer of fluid at heat-generating structure 102. As a result, transfer of heat from heat-generating structure 102 may be improved. The fluid travels along the surface of heat-generating structure 102. Thus, heat from heat-generating structure 102 may be extracted by the fluid. The fluid may exit the region between orifice plate 130 and heat-generating structure 102 at the edges of cooling system 100. Chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

FIGS. 1E-1F depict an embodiment of active MEMS cooling system 100 including centrally anchored cooling element 120 in which the cooling element is driven out-of-phase. More specifically, sections of cooling element 120 on opposite sides of anchor 160 (and thus on opposite sides of the central region of cooling element 120 that is supported by anchor 160) are driven to vibrate out-of-phase. In some embodiments, sections of cooling element 120 on opposite sides of anchor 160 are driven at or near one hundred and eighty degrees out-of-phase. Thus, one section of cooling element 120 vibrates toward top plate 110, while the other section of cooling element 120 vibrates toward orifice plate 130/heat-generating structure 102. Thus, one section of cooling element 120 may carry out an upstroke, while the other section performs a downstroke. Thus, fluid traveling at high speeds (e.g. speeds described with respect to in-phase operation) is alternately driven out of orifices 132 on opposing sides of anchor 160. Because fluid is driven through orifices 132 at high speeds, cooling system 100 may be viewed as a MEMs jet. The net movement of fluid is shown by unlabeled arrows in FIGS. 1E and 1F. However, the unlabeled arrows in FIGS. 1E and 1F are not intended to indicate the motion of fluid at a particular time. The motion between the positions shown in FIGS. 1E and 1F is repeated. Thus, cooling element 120 undergoes vibrational motion indicated in FIGS. 1A, 1E, and 1F, alternately drawing fluid through vent 112 from the distal side of top plate 110 into top chamber 140 for each side of cooling element 120; transferring fluid from each side of top chamber 140 to the corresponding side of bottom chamber 150; and pushing the fluid through orifices 132 on each side of anchor 160 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at the frequencies described for in-phase vibration. The structural resonant frequency of cooling element 120 is within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 for out-of-phase vibration may move in a manner analogous to that described above for in-phase operation. Similarly, chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

Although shown in the context of a uniform cooling element in FIGS. 1A-1F, cooling system 100 may utilize cooling elements having different shapes. FIG. 1G depicts an embodiment of engineered cooling element 120′ having a tailored geometry and usable in a cooling system such as cooling system 100. Cooling element 120′ includes an anchored region 122 and cantilevered arms 123. Anchored region 122 is supported (e.g. held in place) in cooling system 100 by anchor 160. Cantilevered arms 123 undergo vibrational motion in response to cooling element 120′ being actuated. Each cantilevered arm 123 includes step region 124, extension region 126 and outer region 128. In the embodiment shown in FIG. 1G, anchored region 122 is centrally located. Step region 124 extends outward from anchored region 122. Extension region 126 extends outward from step region 124. Outer region 128 extends outward from extension region 126. In other embodiments, anchored region 122 may be at one edge of the actuator and outer region 128 at the opposing edge. In such embodiments, the actuator is edge anchored.

Extension region 126 has a thickness (extension thickness) that is less than the thickness of step region 124 (step thickness) and less than the thickness of outer region 128 (outer thickness). Thus, extension region 126 may be viewed as recessed. Extension region 126 may also be seen as providing a larger bottom chamber 150. In some embodiments, the outer thickness of outer region 128 is the same as the step thickness of step region 124. In some embodiments, the outer thickness of outer region 128 is different from the step thickness of step region 124. In some embodiments, outer region 128 and step region 124 each have a thickness of at least three hundred twenty micrometers and not more than three hundred and sixty micrometers. In some embodiments, the outer thickness is at least fifty micrometers and not more than two hundred micrometers thicker than the extension thickness. Stated differently, the step (difference in step thickness and extension thickness) is at least fifty micrometers and not more than two hundred micrometers. In some embodiments, the outer step (difference in outer thickness and extension thickness) is at least fifty micrometers and not more than two hundred micrometers. Outer region 128 may have a width, q, of at least one hundred micrometers and not more than three hundred micrometers. Extension region 126 has a length, e, extending outward from the step region of at least 0.5 millimeter and not more than 1.5 millimeters in some embodiments. In some embodiments, outer region 128 has a higher mass per unit length in the direction from anchored region 122 than extension region 126. This difference in mass may be due to the larger size of outer region 128, a difference in density between portions of cooling element 120, and/or another mechanism.

Use of engineered cooling element 120′ may further improve efficiency of cooling system 100. Extension region 126 is thinner than step region 124 and outer region 128. This results in a cavity in the bottom of cooling element 120′ corresponding to extension region 126. The presence of this cavity aids in improving the efficiency of cooling system 100. Each cantilevered arm 123 vibrates towards top plate 110 in an upstroke and away from top plate 110 in a downstroke. When a cantilevered arm 123 moves toward top plate 110, higher pressure fluid in top chamber 140 resists the motion of cantilevered arm 123. Furthermore, suction in bottom chamber 150 also resists the upward motion of cantilevered arm 123 during the upstroke. In the downstroke of cantilevered arm 123, increased pressure in the bottom chamber 150 and suction in top chamber 140 resist the downward motion of cantilevered arm 123. However, the presence of the cavity in cantilevered arm 123 corresponding to extension region 126 mitigates the suction in bottom chamber 150 during an upstroke. The cavity also reduces the increase in pressure in bottom chamber 150 during a downstroke. Because the suction and pressure increase are reduced in magnitude, cantilevered arms 123 may more readily move through the fluid. This may be achieved while substantially maintaining a higher pressure in top chamber 140, which drives the fluid flow through cooling system 100. Moreover, the presence of outer region 128 may improve the ability of cantilevered arm 123 to move through the fluid being driven through cooling system 100. Outer region 128 has a higher mass per unit length and thus a higher momentum. Consequently, outer region 128 may improve the ability of cantilevered arms 123 to move through the fluid being driven through cooling system 100. The magnitude of the deflection of cantilevered arm 123 may also be increased. These benefits may be achieved while maintaining the stiffness of cantilevered arms 123 through the use of thicker step region 124. Further, the larger thickness of outer region 128 may aid in pinching off flow at the bottom of a downstroke. Thus, the ability of cooling element 120′ to provide a valve preventing backflow through orifices 132 may be improved. Thus, performance of cooling system 100 employing cooling element 120′ may be improved.

Further, cooling elements used in cooling system 100 may have different structures and/or be mounted differently than depicted in FIGS. 1A-1G. In some embodiments, the cooling element may have rounded corners and/or rounded ends but still be anchored along a central axis such that cantilevered arms vibrate. The cooling element may be anchored only at its central region such that the regions surrounding the anchor vibrate in a manner analogous to a jellyfish or the opening/closing of an umbrella. In some such embodiments, the cooling element may be circular or elliptical in shape. In some embodiments, the anchor may include apertures through which fluid may flow. Such an anchor may be utilized for the cooling element being anchored at its top (e.g. to the top plate). Although not indicated in FIGS. 1A-1G, the piezoelectric material utilized in driving the cooling element may have various locations and/or configurations. For example, the piezoelectric material may be embedded in the cooling element, affixed to one side of the cooling element (or cantilevered arm(s)), may occupy some or all of the cantilevered arms, and/or may have a location that is close to or distal from the anchored region. In some embodiments, cooling elements that are not centrally anchored may be used. For example, a pair of cooling elements that have offset apertures, that are anchored at their ends (or all edges), and which vibrate out of phase may be used. Thus, various additional configurations of cooling element 120 and/or 120′, anchor 160, and/or other portions of cooling system 100 may be used.

Using the cooling system 100 actuated for in-phase vibration or out-of-phase vibration of cooling element 120 and/or 120′, fluid drawn in through vent 112 and driven through orifices 132 may efficiently dissipate heat from heat-generating structure 102. Stated differently, heat transfer between heat-generating structure 102 and the moving fluid is improved. Because the heat-generating structure is more efficiently cooled, the corresponding integrated circuit may be run at higher speed and/or power for longer times. For example, if the heat-generating structure corresponds to a high-speed processor, such a processor may be run for longer times before throttling. Thus, performance of a device utilizing cooling system 100 may be improved. Further, cooling system 100 may be a MEMS device. Consequently, cooling systems 100 may be suitable for use in smaller and/or mobile devices, such as smart phones, other mobile phones, virtual reality headsets, tablets, two-in-one computers, wearables and handheld games, in which limited space is available. Performance of such devices may thus be improved. Because cooling element 120/120′ may be vibrated at frequencies of 15 kHz or more, users may not hear any noise associated with actuation of cooling elements. If driven at or near structural and/or acoustic resonant frequencies, the power used in operating cooling systems may be significantly reduced. Cooling element 120/120′ may not physically contact top plate 110 or orifice plate 130 during vibration in normal operation. Thus, resonance of cooling element 120/120′ may be more readily maintained. Issues related to moving away from resonance may be mitigated or avoided through the use of pressure differentials and fluid flow as discussed above. The benefits of improved, quiet cooling may be achieved with limited additional power. Further, out-of-phase vibration of cooling element 120/120′ allows the position of the center of mass of cooling element 120/120′ to remain more stable. Although a torque is exerted on cooling element 120/120′, the force due to the motion of the center of mass is reduced or eliminated. As a result, vibrations due to the motion of cooling element 120/120′ may be reduced. Moreover, efficiency of cooling system 100 may be improved through the use of out-of-phase vibrational motion for the two sides of cooling element 120/120′. Consequently, performance of devices incorporating the cooling system 100 may be improved. Further, cooling system 100 may be usable in other applications (e.g. with or without heat-generating structure 102) in which high fluid flows and/or velocities are desired.

In addition, cooling system 100 may have a high back pressure. Back pressure is a measure of the resistance to a fluid flow driven through a system. The back pressure may be considered to be the pressure at which flow through the system goes to zero. Stated differently, the back pressure may be the pressure at which the system can no longer drive fluid flow. Cooling system 100 may have a high back pressure. For example, in some embodiments, the back pressure of cooling system 100 may be on the order of 2 kPa. Depending upon the geometry and fluid used, higher back pressures may be possible. For example, the back pressure of cooling system 100 may be on the order of 6-11 kPa in some embodiments. In some embodiments, the back pressure of cooling system 100 may be 8-10 kPa. As such, system 100 may be capable of driving fluid, and cooling heat-generating structure 102, even at higher pressures (e.g., 2 kPa, 6 kPa, or up to 8-10 kPa).

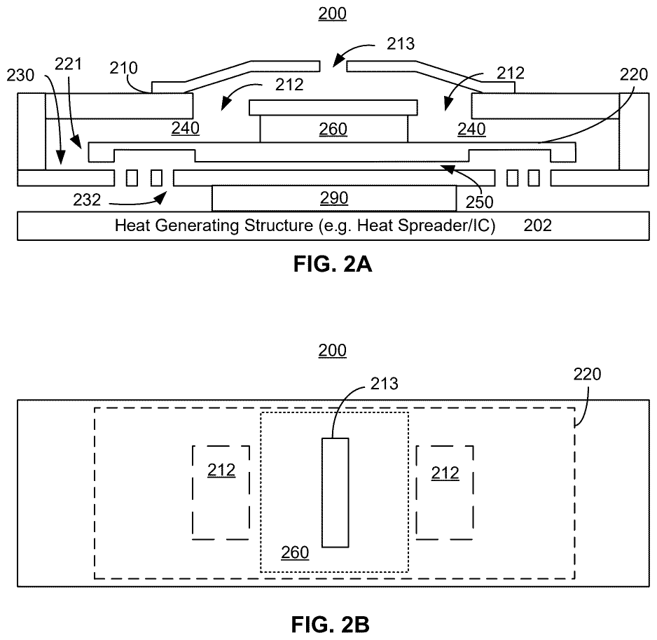

FIGS. 2A-2B depict an embodiment of active MEMS cooling system 200 including a top centrally anchored cooling element. FIG. 2A depicts a side view of cooling system 200 in a neutral position. FIG. 2B depicts a top view of cooling system 200. FIGS. 2A-2B are not to scale. For simplicity, only portions of cooling system 200 are shown. Referring to FIGS. 2A-2B, cooling system 200 is analogous to cooling system 100. Consequently, analogous components have similar labels. For example, cooling system 200 is used in conjunction with heat-generating structure 202, which is analogous to heat-generating structure 102.

Cooling system 200 includes top plate 210 having vents 212, cooling element 220 having tip 221, orifice plate 230 including orifices 232, top chamber 240 having a gap, bottom chamber 250 having a gap, flow chamber 240/250, and anchor (i.e. support structure) 260 that are analogous to top plate 110 having vent 112, cooling element 120 having tip 121, orifice plate 130 including orifices 132, top chamber 140 having gap 142, bottom chamber 150 having gap 152, flow chamber 140/150, and anchor (i.e. support structure) 160, respectively. Also shown is pedestal 290 analogous to pedestal 190. Thus, cooling element 220 is centrally supported by anchor 260 such that at least a portion of the perimeter of cooling element 220 is free to vibrate. In some embodiments, anchor 260 extends along the axis of cooling element 220. In other embodiments, anchor 260 is only near the center portion of cooling element 220. Although not explicitly labeled in FIGS. 2A and 2B, cooling element 220 includes an anchored region and cantilevered arms including step region, extension region, and outer regions analogous to anchored region 122, cantilevered arms 123, step region 124, extension region 126, and outer region 128 of cooling element 120'. In some embodiments, cantilevered arms of cooling element 220 are driven in-phase. In some embodiments, cantilevered arms of cooling element 220 are driven out-of-phase. In some embodiments, a simple cooling element, such as cooling element 120, may be used. Further, although cavities analogous to cavities 134 and 135 are not depicted in cooling system 200, such cavities may be present.

Anchor 260 supports cooling element 220 from above. Thus, cooling element 220 is suspended from anchor 260. Anchor 260 is suspended from top plate 210. Top plate 210 includes vent 213. Vents 212 on the sides of anchor 260 provide a path for fluid to flow into sides of chamber 240.

As discussed above with respect to cooling system 100, cooling element 220 may be driven to vibrate at or near the structural resonant frequency of cooling element 220. Further, the structural resonant frequency of cooling element 220 may be configured to align with the acoustic resonance of chamber 240/250. The structural and acoustic resonant frequencies are generally chosen to be in the ultrasonic range. For example, the vibrational motion of cooling element 220 may be at the frequencies described with respect to cooling system 100. Consequently, efficiency and flow rate may be enhanced. However, other frequencies may be used.

Cooling system 200 operates in an analogous manner to cooling system 100. Cooling system 200 thus shares the benefits of cooling system 100. Thus, performance of a device employing cooling system 200 may be improved. In addition, suspending cooling element 220 from anchor 260 may further enhance performance. In particular, vibrations in cooling system 200 that may affect other cooling cells (not shown) may be reduced. For example, less vibration may be induced in top plate 210 due to the motion of cooling element 220. Consequently, cross talk between cooling system 200 and other cooling systems (e.g. other cells) or other portions of the device incorporating cooling system 200 may be reduced. Thus, performance may be further enhanced.

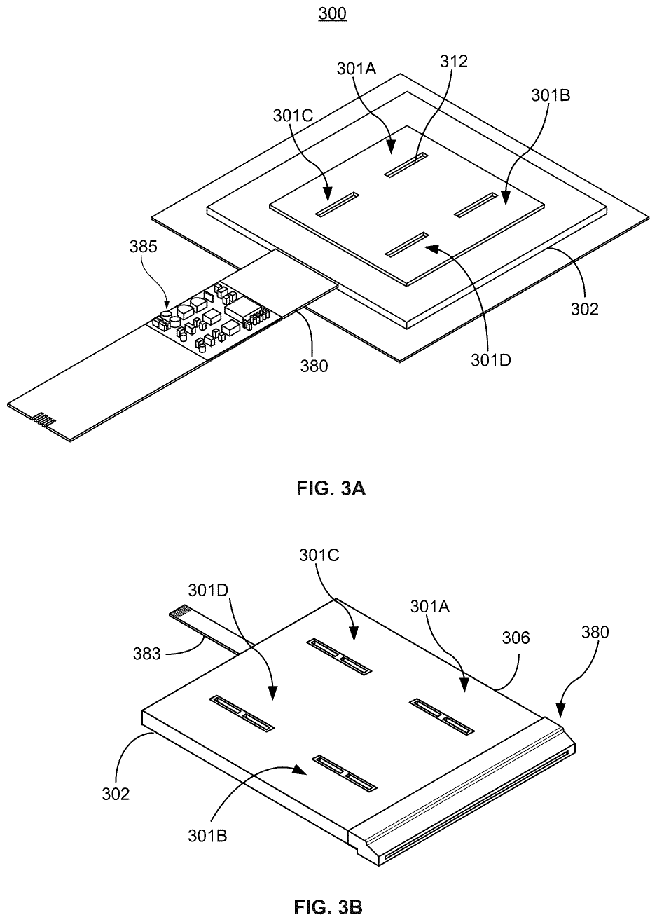

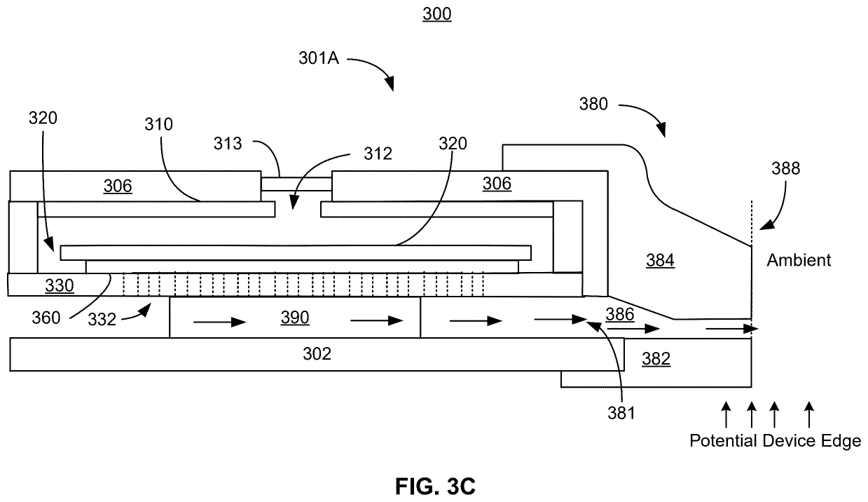

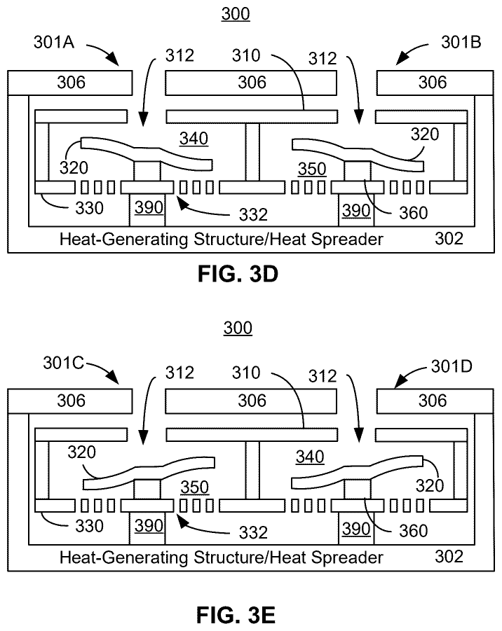

FIGS. 3A-3E depict an embodiment of active MEMS cooling system 300 including multiple cooling cells configured as a module termed a tile, or array. FIG. 3A depicts a perspective view with spout 380 removed. FIG. 3B depicts active MEMS cooling system 300 with cover 306 and spout 380. FIG. 3C depicts a side view of a portion of cooling system 300. FIGS. 3D-3E depict side/cross-sectional views of cooling system 300. FIGS. 3A-3E are not to scale. Cooling system 300 includes four cooling cells 301A, 301B, 301C and 301D (collectively or generically 301), which are analogous to one or more of cooling systems described herein. More specifically, cooling cells 301 are analogous to cooling system 100 and/or 200. Tile 300 thus includes four cooling cells 301 (i.e. four MEMS jets). Although four cooling cells 301 in a 2×2 configuration are shown, in some embodiments another number and/or another configuration of cooling cells 301 might be employed. In the embodiment shown, cooling cells 301 include shared top plate 310 having apertures 312, cooling elements 320, shared orifice plate 330 including orifices 332, top chambers 340, bottom chambers 350, anchors (support structures) 360, and pedestals 390 that are analogous to top plate 110 having apertures 112, cooling element 120, orifice plate 130 having orifices 132, top chamber 140, bottom chamber 150, anchor 160, and pedestal 190. In some embodiments, cooling cells 301 may be fabricated together and separated, for example by cutting through top plate 310, side walls between cooling cells 301, and orifice plate 330. Thus, although described in the context of a shared top plate 310 and shared orifice plate 330, after fabrication cooling cells 301 may be separated. In some embodiments, tabs (not shown) and/or other structures such as anchors 360 may connect cooling cells 301. Although not shown, cooling cells 301 may have cavities analogous to cavities 114, 134, and/or 135. Further, tile 300 includes heat-generating structure (termed a heat spreader hereinafter) 302 (e.g. a heat sink, a heat spreader, and/or other structure) that also has sidewalls, or fencing, in the embodiment shown. Cover 306 having apertures therein is also shown. In some embodiments, a dust filter (not shown) may be provided for the apertures. In such embodiments, dust may be less likely to reach the interior of cooling system 300. In some embodiments, a water tight, air porous membrane may be provided for the apertures. Heat spreader 302, cover 306, and spout 380 may be part of an integrated tile 300 as shown or may be separate from tile 300 in other embodiments. Heat spreader 302 and cover plate 306 may direct fluid flow outside of cooling cells 301, provide mechanical stability, and/or provide protection. Electrical connection to cooling cells 301 is provided via flex connector 380 (not shown in FIGS. 3C-3E) which may house drive electronics 385. Cooling elements 320 are driven out-of-phase (i.e. in a manner analogous to a see-saw). Further, as can be seen in FIGS. 3D-3E cooling element 320 in one cell is driven out-of-phase with cooling element(s) 320 in adjacent cell(s). Cooling elements 320 in a column are driven out-of-phase. Thus, cooling element 320 in cell 301A is out-of-phase with cooling element 320 in cell 301C. Similarly, cooling element 320 in cell 301B is out-of-phase with cooling element 320 in cell 301D. By driving cooling elements 320 out-of-phase, vibrations in cooling system 300 may be reduced. Cooling elements 320 may be driven in another manner in some embodiments. For example, cooling elements 301A and 301C may be driven in-phase but out-of-phase with cooling element 301B and 301D.

Cooling system 300 may also include spout 380 having dissipation region 386 therein. Thus, cooling system 300 including top cover 306 and heat spreader 302 may have a total thickness not exceeding four millimeters. In some embodiments, the height of cooling system 300 does not exceed 3.5 millimeters. In some embodiments, the height of cooling system 300 does not exceed 3 millimeters. In some embodiments, cooling system 300 has a height of at least 2 millimeters. Spout 380 includes a housing having bottom 382 and top 384, entrance 381 and exit 386. Entrance 381 is fluidically coupled with orifices 332 (i.e. egresses from flow chamber 340/350). The direction of fluid flow from flow chamber 340/350 may be seen by the unlabeled arrows in FIG. 3C. Spout 380 operates to smooth pulsations in the pressure waves generated by cooling elements 320. Because cooling elements 320 vibrate, the flow of fluid pulsates. Thus, the pressure of the fluid also pulsates between higher and lower pressures. Flow may also exit orifices 332 and travel through the jet channel in pulses. The pressure within flow chamber 340/350 and the jet channel is higher than the pressure of the ambient region. The fluid exits the jet channel and enters spout 380 at entrance 381. The fluid travels through dissipation region 386 and to exit 388. The pulsating pressure in the fluid is dissipated in dissipation region 384. Stated differently, the pulsations in pressure may be attenuated such that the pressure equilibrates and approaches (or reaches) the ambient pressure of the ambient region outside of system 300. In some embodiments, therefore, the pressure of the fluid at exit 388 of spout 380 matches or substantially the boundary conditions for the pressure of the ambient. In some embodiments of cooling system 300, spout 380 may be omitted. Also shown in FIG. 3C is optional dust guard 313. Dust guard 313 may be a MERV 14 or other analogous filter used to reduce or eliminate small particles from entering cooling system 300. Further, although cavities analogous to cavities 134 are not depicted in cooling system 300, such cavities may be present.

Cooling cells 301 of cooling system 300 function in an analogous manner to cooling system(s) 100, 200, and/or an analogous cooling system. Consequently, the benefits described herein may be shared by cooling system 300. Because cooling elements in nearby cells are driven out-of-phase, vibrations in cooling system 300 may be reduced. Because multiple cooling cells 301 are used, cooling system 300 may enjoy enhanced cooling capabilities. Further, multiples of individual cooling cells 301 and/or cooling system 300 may be combined in various fashions to obtain the desired footprint of cooling cells.

According to various embodiments, the system comprises a dust guard. The dust guard be implemented to provide filtration of fluids input to a cooling system.

In some embodiments, the dust guard is a cooling system dust guard that couples directly to a MEMS cooling system. The MEMS cooling system uses vibrational motion to drive a fluid (e.g., air). The cooling system dust guard includes a filter (e.g. a MERV 14 filter) and a carrier used to hold the filter and couple to the MEMS cooling system. In some embodiments, the carrier is flexible. The carrier may include a manifold coupling the cooling system dust guard to the carrier. A shim may be included proximate to inlets to the MEMS cooling system. The shim may prevent the filter from collapsing onto the inlets. For example, a stainless steel shim having a thickness of at least 40 micrometers and not more than 70 micrometers (e.g. nominally 50 micrometers) may be used.

In some embodiments, the cooling system dust guard is coupled to the MEMS cooling system proximate to a connection to a flex connector (the back of the cooling system).

In some embodiments, the cooling system dust guard is coupled to the side of the MEMS cooling system. Thus, the cooling system dust guard does not capture fluid exiting the cooling system. The cooling system dust guard is connected to the MEMS cooling system such that fluid passes through the filter before entering the cooling system.

In some embodiments, the dust guard may be a system dust guard coupled with a device in which the MEMS cooling system is used. The system dust guard may be in proximity to aperture(s) in the device through which fluid (e.g., air) enters. The system dust guard may include a filter, such as a MERV 14 filter or an even finer filter. The filter may be recessed from the aperture(s). Closer to the aperture(s), a hydrophobic mesh may be present. The hydrophobic mesh may function as a spill guard.

The system dust guard may be used in conjunction with the cooling system dust guard. In some embodiments, the cooling system dust guard replaces the filter of the system dust guard. Thus, the hydrophobic mesh may be used with the cooling system dust guard. Using one or more of the dust guards described herein, dust may be prevented from entering the device and/or the MEMS cooling system. Consequently, the reliability and lifetime of the MEMS cooling system may be improved.

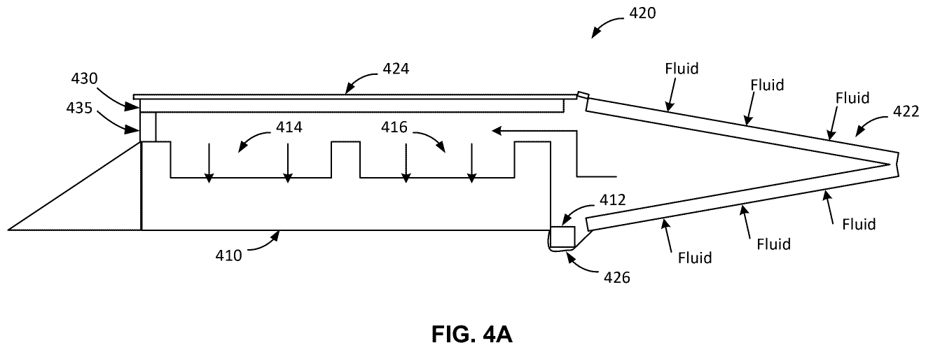

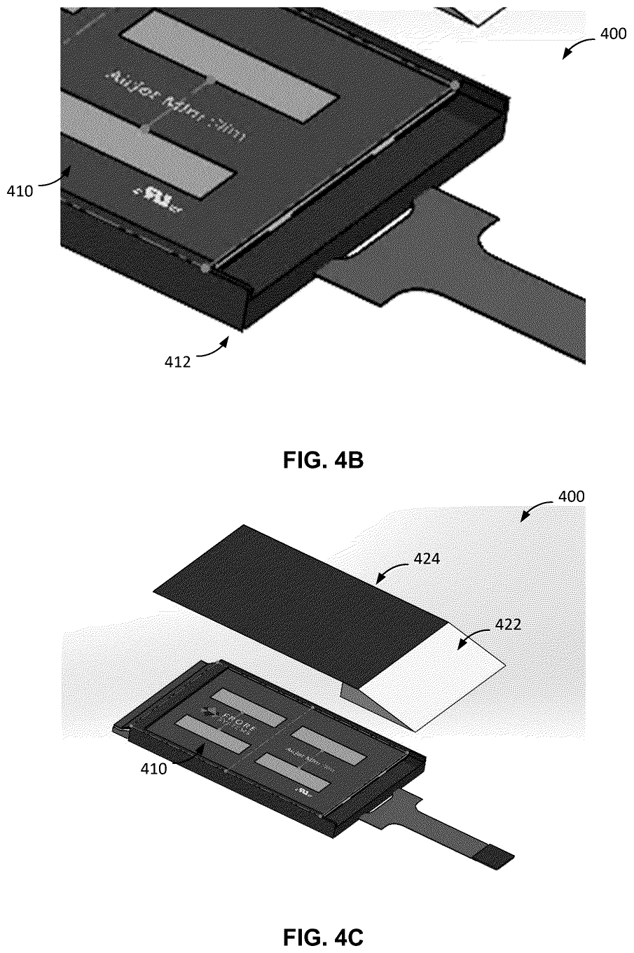

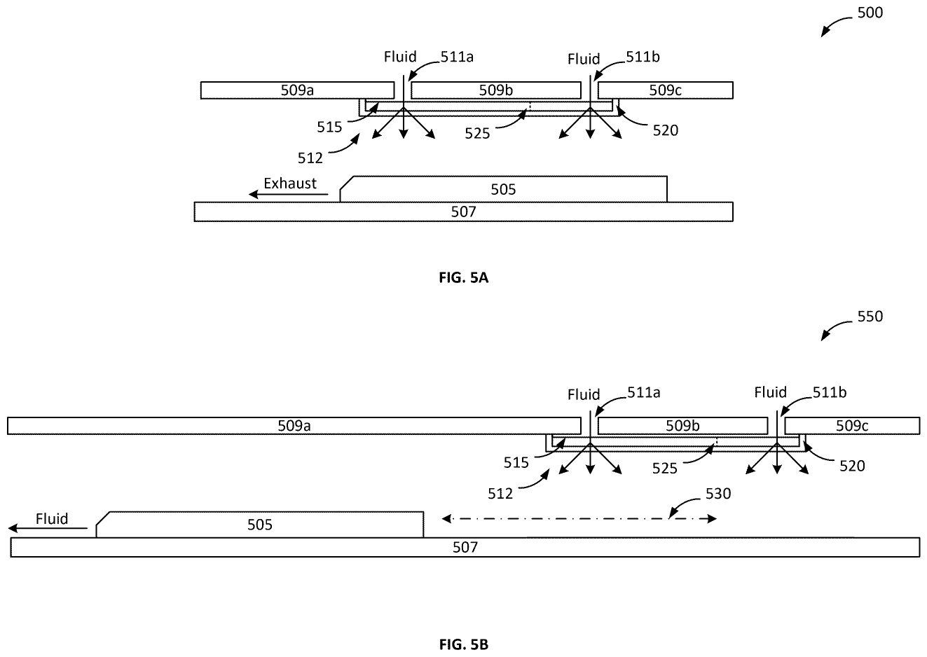

FIGS. 4A-4C depict an embodiment of a filtration system for a MEMS cooling system. FIG. 4A depicts a side view of a system 400 comprising a cooling system 410 and a filtration system 420. FIG. 4B depicts a cutaway view of system 400. FIG. 4C depicts a partially exploded view of system 400.

In some embodiments, system 400 comprises a filtration system (e.g., filtration system 420) such as a sleeve dust guard. The sleeve dust guard is provided to enhance the reliability and effectiveness of a cooling system, such as a MEMS-based cooling system (e.g., cooling system 410), by preventing particulate contamination of the cooling elements. As illustrated in FIG. 4A, in some embodiments, the sleeve dust guard (e.g., filtration system 420) is securely coupled to or encapsulates the cooling system (e.g., cooling system 410) such that all fluid entering the cooling system is directed exclusively through a fine filter. The fine filter may be a high-efficiency particulate filter (e.g., MERV 14 or better) that effectively captures fine airborne/fluid borne particles, thus maintaining optimal airflow and cooling performance, and consequently extending the operating lifetime of cooling system 400. Encapsulation of the cooling system, or at least its air intake regions, may be achieved using adhesive tape, a fitted manifold, or other suitable cover systems designed to ensure an airtight seal around the cooling structure except where the fine filter is located. In the example shown, filtration system comprises layer 424 that seals the air intake regions (e.g., inlets 414 and 416) to ensure that the fluid (e.g., air) enters the air intake regions via filter 422 (e.g., the fine filter). As a result, ambient air entering the cooling system is constrained to flow solely through the fine filter. In some implementations, filtration system 420 extends up to 50% of the length of cooling system 410.

In some embodiments, the fine filter may be constructed from or supported by a rigid material or framework to prevent collapse or deformation of the fine filter (e.g., filter 422), especially under conditions of higher airflow rates or pressure differentials. For example, the fine filter may be secured onto or reinforced by a rigid scaffold, frame, or grid structure, which may be made from metal, plastic, or other suitably robust materials. This structural support ensures consistent spacing and surface area for airflow, preserving the filtration effectiveness and reducing pressure drop across the fine filter. In addition, layer 424 and layer 426 (e.g., a tape or sealant) are supported on a rigid structure 430 (e.g., a stiffener). Rigid structure 430 may be a shim made of a metal or alloy, such as steel. In some implementations, rigid structure 430 is a steel shim that is between 10 and 20 microns thick. In some implementations, the thickness of rigid structure is 15 microns. Rigid structure 430 may be supported by support structure 435 configured on cooling system 410 to provide sufficient clearance for a fluid pathway from filter 422 to inlets 414 and 416. On the other end of filter 422, layer 426 is used as the manifold configured/used to seal and contain the cavity defining the fluid pathways from filter 422 to inlets 414, 416. Layer 426 can seal the interface between filter 422 and frame structure 412.

In some embodiments, the sleeve dust guard (e.g., filtration system 420) is integrated within an electronic device in such a manner that air supplied to the cooling system 410 has already undergone preliminary filtration through a coarse filter located at or near the device's external inlet apertures. The coarse filter may be a low-pressure-drop hydrophobic mesh filter (e.g., Saatifil), acting primarily as a pre-filter and splash guard. By providing initial filtration at the entry point of the device, large particles and contaminants, as well as water droplets, are substantially prevented from entering the device's interior. Subsequently, the partially filtered airflow passes into the sleeve dust guard (e.g., filtration system 420) and is directed through the fine filter into the cooling system.

The combination of the coarse pre-filter and the fine filter in the sleeve dust guard arrangement offers dual-stage filtration, enhancing contaminant removal while maintaining efficient airflow dynamics. The coarse pre-filter significantly reduces larger particulates, thereby extending the lifetime and efficiency of the fine filter. Moreover, the encapsulation provided by the sleeve dust guard ensures that no air bypasses the fine filter, guaranteeing that airflow entering the MEMS cooling system remains substantially free from contaminants. Consequently, the reliability, thermal performance, and operational longevity of both the cooling system and the electronic device incorporating the cooling system are significantly improved.

According to various embodiments, the system (e.g., a filtration system) is configured to provide a plurality of filtration layers. For example, the system is configured to provide double filtration. The filtration system may comprise a coarse filter and a fine filter. The coarse filter may be a hydrophobic mesh (e.g., Saatifil) that is a low-pressure-drop coarse mesh filter. In some embodiments, the coarse filter is attached directly to the slot inlet wall, or in close proximity to the slot inlet wall. The coarse filter may additionally act as a splash guard. The fine filter (e.g., a MERV14 filter) does most of the dust filtering, but has a much higher pressure drop. The pressure drop increases as the velocity of air flow through the filter increases. This pressure drop across the fine filter causes a flow drop, thereby reducing the fluid influx to the cooling system.

In some embodiments, the fine filter is disposed a certain distance away from the coarse filter to form a filter gap between the fine filter and the coarse filter. The air that passes through the coarse filter is diffused within the filter gap before passing through the fine filter. This diffusion within the filter gap dramatically reduces the air velocity through the fine filter, thus reducing/minimizing flow loss. For example, the air diffuses within the filter gap so that a larger surface area of the fine filter is used to pass the influx fluid.

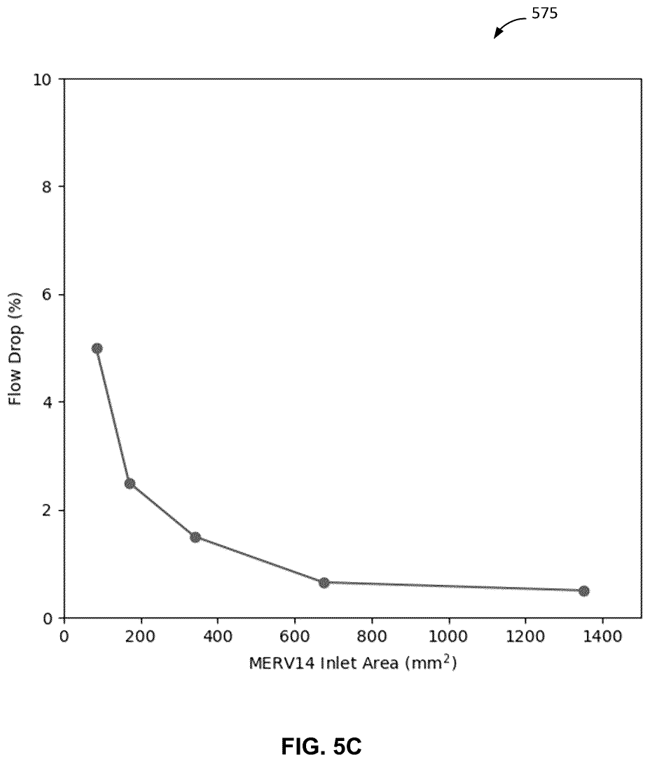

FIGS. 5A-5B depict an embodiment of a filtration system for a MEMS cooling system. FIG. 5A depicts a side view of system 500 comprising a filtration system 512 and cooling system 505 where cooling system 505 is vertically aligned (or substantially vertically aligned) with filtration system 512. FIG. 5B depicts a side view of system 550 comprising a filtration system 512 and cooling system 505 where cooling system 505 is not vertically aligned with filtration system 512, for example, cooling system 505 is horizontally displaced with respect to filtration system 512 (e.g., because of electronic device design considerations or to increase the cavity through which intake air flows to properly diffuse across the cooling system intake area).

According to various embodiments, system 500 comprises a filtration system 512, such as a system dust guard. The system dust guard is provided to effectively reduce particulate contamination within electronic devices utilizing active cooling systems, such as MEMS-based cooling solutions (e.g., cooling system 505). The system dust guard is configured to integrate both coarse and fine filtration stages positioned strategically along an airflow pathway leading into the cooling system. For example, filtration system 512 comprises coarse filter 510 and fine filter 520. Specifically, the coarse filter 515 may be disposed at or near the inlet wall (e.g., the inlets between wall segments such as wall segments 509a, 509b, and/or 509c) of a cavity containing the cooling system 505, serving as an initial barrier to capture larger particulates and potential liquid ingress. This coarse filter may comprise a hydrophobic mesh, such as a Saatifil filter, characterized by its relatively low pressure drop and ability to efficiently block larger particles, droplets, and splashes without significantly obstructing airflow. In the example shown, air flows into the system (e.g., filtration system) through air inlet 511a and/or air inlet 511b.

In some embodiments, further downstream along the airflow pathway, the filtration system 512 provides a fine filter 520. Fine filter 520 is positioned so that air flowing from the coarse filter 515 is subsequently directed through the fine filter 520. The fine filter 520 may be a high-efficiency particulate air filter (e.g., MERV 14 or better), configured to capture smaller airborne contaminants that pass through the coarse filter 515. The spatial separation between the coarse and fine filters is termed the filter gap, and this gap is specifically dimensioned and configured to optimize the pressure drop and airflow dynamics across the fine filter. In the example shown, the filter gap is defined by distance 525 between the output layer of the coarse filter 515 and the input layer of the fine filter 520. By adjusting the filter gap, air output from the coarse filter diffuses sufficiently, spreading across a larger effective surface area of the fine filter rather than impacting a narrow region directly. For instance, the fine filter may be placed at a distance sufficient to achieve a predefined flow drop threshold, such as approximately 2% to 3.5%. Increasing the filter gap allows the airflow to evenly distribute, thus minimizing localized high velocities and reducing overall airflow resistance through the fine filter.

In some embodiments, the filter gap is sufficiently large that a flow of the fluid through the fine filter reduces the fluid flow by less than or equal to 3.0 percent of a fluid flow without the fine filter and coarse filter being positioned in a fluid flow pathway.

In some embodiments, the cooling system is arranged such that it is positioned to be aligned with the fine filter. For example, the cooling system is horizontally aligned with, or vertically below, the fine filter. As illustrated in FIG. 5A, in this configuration, airflow emerging from the fine filter 520 directly flows downward into the cooling system 505 without significant obstruction or redirection. This vertical alignment allows for efficient and direct transfer of filtered air into the cooling elements, enhancing cooling efficiency and thermal management performance by ensuring minimal airflow loss and reduced turbulence.

In some embodiments, the cooling system may be horizontally offset relative to the filtration subsystem. As shown in FIG. 5B, in such configurations, air exiting from the fine filter 520 enters a cavity formed between an inlet wall (to which the filtration subsystem is attached, such as inlet wall defined by wall segments 509a-509c) and a heat spreader 507 or another thermally conductive structure within the electronic device. In this example, system 500 comprises cooling system 505 horizontally displaced from filtration system 512 by distance 530. Air entering this cavity flows horizontally across the surface of the cooling system 505, effectively transferring heat away from heat-generating components toward an exhaust outlet. This horizontal displacement approach enables the airflow pathway to serve dual functions:
delivering filtered air to the cooling system and facilitating effective heat dissipation by directing airflow across heat-generating surfaces.

Consequently, the two-stage filtration system of some embodiments, with carefully controlled spacing and arrangement of coarse and fine filters, significantly enhances the cleanliness of air reaching sensitive cooling components while optimizing airflow performance. The design maintains effective particulate removal and airflow efficiency, reducing pressure losses and improving overall cooling performance, device reliability, and operational longevity.

FIG. 5C depicts a relationship between a fine filter inlet area and a drop in fluid flow according to various embodiments. As shown in graph 575, at various filter inlet area (which may be a proxy for various filter gap sizes), expected flow loss % can be predicted as shown. The expected loss percentage can be computed based on a device PQ curve for an air jet and a pressure cost curve for the system. The intersection between the device PQ curve and the system pressure cost curve can be used to predict the expected flow and the pressure cost necessary to make the flow happen through the device. In some embodiments, this intersection point depends on the system pressure cost curve, which is dependent upon the filter inlet area. In some embodiments, the fine filter inlet area may be a proxy for the volume or cross sectional area of the filter gap. A gap of at least 200 micrometers may be desired. In some embodiments, the fine filter and the coarse filter are configured so the flow drop is between two percent (2%) and three and one half percent (3.5%).

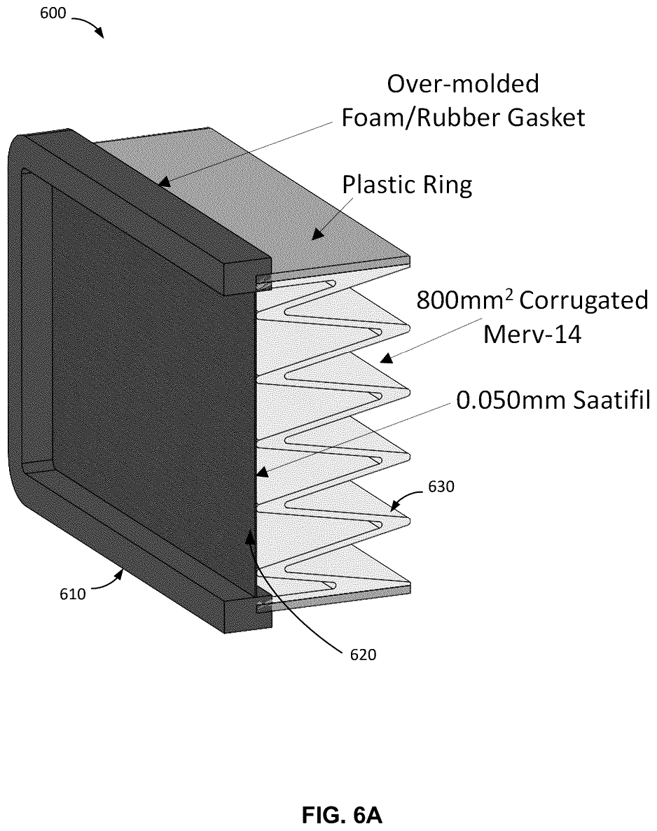

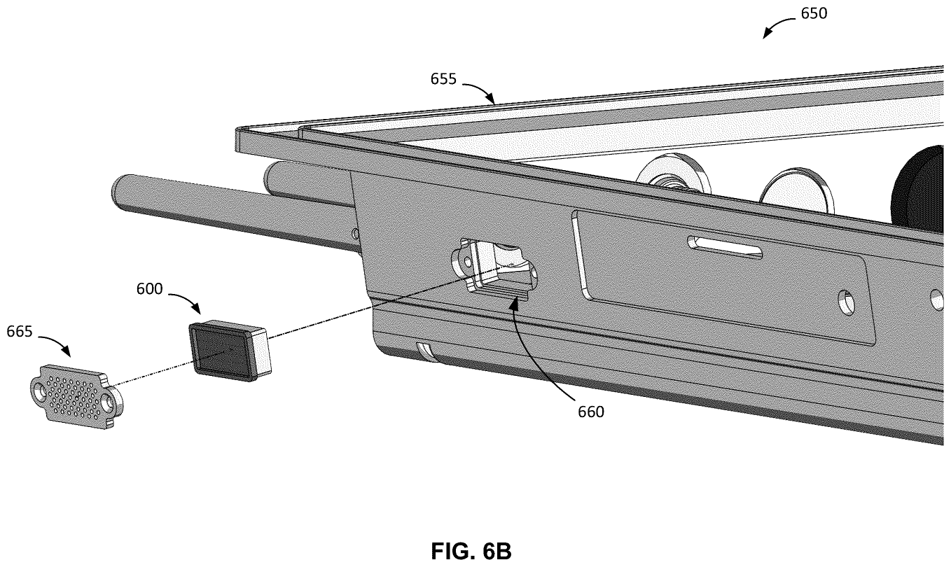

FIGS. 6A-6B depict an embodiment of a filtration system for a MEMS cooling system. FIG. 6A depicts a cutaway view of filtration system 600. FIG. 6B depicts an exploded view of a system 650 comprising filtration system 600.

In some embodiments, the system comprises a filtration system where the system and/or filtration system are configured so the filtration system is replaceable. For example, a replaceable system dust guard is provided to efficiently manage particulate contamination within electronic devices that utilize active cooling systems, such as MEMS-based cooling modules. This dust guard (e.g., filtration system 600) is configured as a modular filtration unit comprising both coarse and fine filters, designed to facilitate ease of installation and replacement. In the examples shown in FIG. 6A, filtration system 600 comprises frame 610 (e.g., a support structure), coarse filter 620, and fine filter 630. The dust guard may be positioned at or coupled to an inlet of an electronic device (e.g., system 650), or at an entrance to a cavity or volume housing the cooling system and associated heat-generating structures, such as heat spreaders or processors. In the example shown in FIG. 6B, filtration system 600 may be positioned at cavity (or volume) 660 of housing/frame 655. In some embodiments, system 650 further comprises a cover 665 that is positioned over the filtration system 600. The cover 665 may serve to protect filtration system 600 from damage and/or to hold filtration system 600 in place by connecting cover 665 (e.g., via coupling elements such as screws inserted through a set of through holes of cover 665) to housing/frame 655 at the cavity 660. The modularity of the dust guard allows users to conveniently replace the entire filtration assembly, ensuring continued optimal performance of both filtration and cooling functions.

In some embodiments, the filtration system 600 (e.g., the system dust guard) comprises a coarse pre-filter (e.g., coarse filter 620) and a fine secondary filter (e.g., fine filter 630) arranged sequentially along the airflow path. The coarse filter 620, positioned at or adjacent to the inlet, effectively captures larger particulates and prevents ingress of liquids and larger debris. This coarse filter 620 may be implemented using materials such as a low-pressure-drop hydrophobic mesh (e.g., Saatifil), offering initial robust protection while minimally impacting airflow rates. Positioned downstream, the fine filter 630 provides higher-efficiency particulate filtration (e.g., MERV 14 or better) to capture finer contaminants passing through the coarse filter 620.

The frame 610 of filtration system 600 may comprise a support structure that provides support for the fine filter 630. For example, frame 610 may comprise a plastic ring around the circumference of the filtration system assembly. Frame 610 may also comprise a gasket or cover. For example, frame 610 may comprise an over-molded foam or rubber gasket that supports the fine filter 630, the side support structure, and/or the coarse filter 620.

To optimize filtration performance and airflow efficiency, the fine filter 630 may include a corrugated or pleated design. Corrugation significantly increases the effective filtration surface area available to the airflow, thereby reducing air velocity across the filter medium and minimizing associated pressure drops. In some embodiments, the effective filtration surface area of fine filter 630 is between 600 mm² and 1000 mm². In some embodiments, the effective filtration surface area is between 700 mm² and 900 mm². In some embodiments, the effective filtration surface area is 800 mm². The increased surface area provided by corrugation enhances contaminant capture efficiency and extends the operational lifespan of the fine filter, while also maintaining high airflow rates essential for effective cooling performance.

The dust guard assembly is designed for ease of replacement and may be adapted for installation across a variety of electronic devices, including laptops, tablets, smartphones, desktop computers, gaming systems, augmented and virtual reality devices, and other compact electronic systems requiring active cooling. Installation of the replaceable dust guard may utilize mechanical coupling features such as clips, slots, snap-fit connectors, or magnetic attachments to securely fix the dust guard into position at the device inlet or entry point to the cooling cavity. Such a design allows users or service providers to readily remove and replace the dust guard as part of routine device maintenance, ensuring sustained cooling system effectiveness and device reliability.

According to various embodiments, the combination of modularity, dual-stage filtration, and corrugated fine filter design provided by the replaceable system dust guard (e.g., filtration system 600) results in robust and efficient particulate management. By facilitating straightforward replacement, the filtration system 600 (e.g., the dust guard assembly) helps maintain consistently clean airflow into the cooling systems of electronic devices, thus preserving optimal thermal performance, extending the longevity of sensitive internal components, and improving overall device durability and reliability.

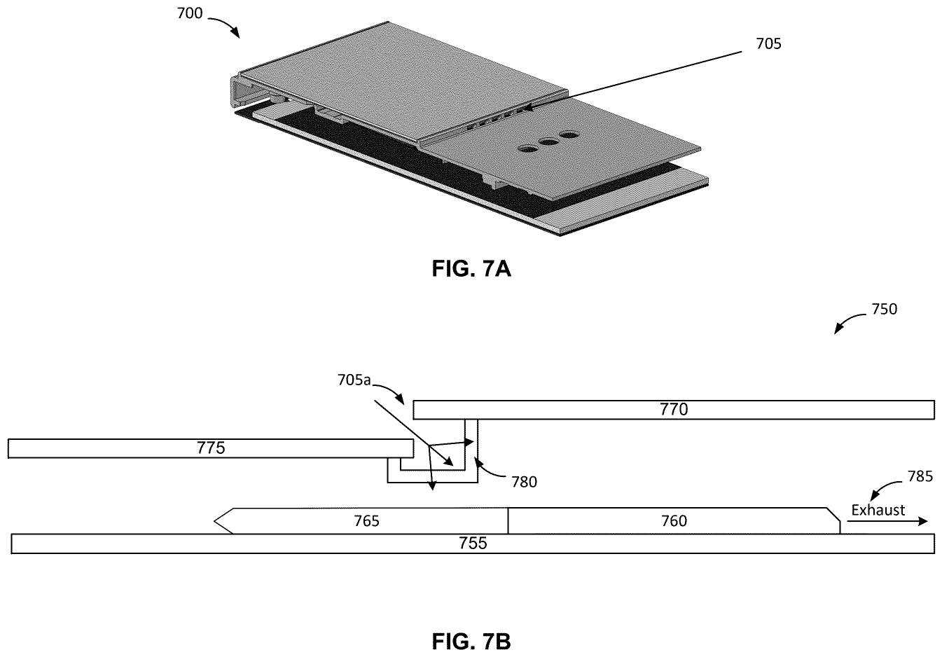

FIGS. 7A-7B depict an embodiment of a filtration system for a MEMS cooling system. FIG. 7A depicts a perspective view of an electronic device assembly, such as at least part of a frame or support structure for an electronic device. FIG. 7B shows a side view of the electronic device comprising a filtration system and a cooling system 760.

In some electronic devices, such as smartphones or tablets, space constraints can limit the ability to accommodate traditional filtration systems that include a defined gap between coarse and fine filters. To address these limitations, various embodiments provide a filtration system in which a coarse filter is strategically integrated into existing external structural features of the device, such as a vertical bump or protrusion commonly associated with cameras or sensors. For instance, a low-pressure-drop coarse filter (e.g., coarse filter 780), such as a hydrophobic mesh (e.g., Saatifil), may be incorporated directly into or adjacent to these external device features. This placement leverages the structural elements of the device to effectively capture larger particulates and prevent water ingress at the earliest point of airflow entry, without requiring additional internal space.

Downstream from this coarse filtration stage, the filtration system comprises a cooling system dust guard (e.g., dust guard 765 comprising a fine filter), similar in function to a sleeve dust guard (e.g., the filtration system illustrated in FIGS. 4A-4C. In some embodiments, the cooling system dust guard 765 incorporates a fine filter, such as a high-efficiency particulate filter (e.g., MERV 14 or better), positioned directly at or around the inlet of the cooling system 760. The fine filter ensures that air entering the cooling system 760 undergoes additional filtration, capturing smaller particles that pass through the coarse filter 780. To ensure that air entering the cooling system cannot bypass the fine filter, the dust guard encapsulates the cooling system or its inlet areas. This encapsulation may be achieved using tape, manifolds, sleeves, or other sealing structures designed to constrain airflow so that it exclusively passes through the fine filter.

The fine filter within the cooling system dust guard 765 may be supported by a rigid scaffold or constructed of rigid filter media, thereby preventing deformation or collapse of the filter under normal operating conditions. This rigidity maintains consistent airflow performance and optimal filtration efficiency, even without a filter gap upstream. Because the initial coarse filtration occurs externally at structural features of the device, such as the camera bump, the fine filter can maintain efficient performance despite the reduced available internal space.

In the example shown in FIG. 7A, electronic device assembly 700 comprises a series of inlets 705. In the example shown in FIG. 7B, system 750 comprises a filtration system and a cooling system 760. FIG. 7B illustrates a cutaway view of electronic device assembly 700 for an inlet 705a of the series of inlets 705 comprised in electronic device assembly 700. Electronic device assembly 700 also comprises wall 770 and wall 775 that are configured to define inlet 705a. Coarse filter 780 is positioned at the opening of inlet 705a. Air filtered by the coarse filter 780 then flows within the electronic device assembly 700 and is filtered by a filter (e.g., a fine filter) in dust guard 765. Thus, air flowing into cooling system 760 is filtered by dust guard 765. However, air flowing through inlet 705a and passing through coarse filter 780 may additionally carry heat away as it flows over the surface of cooling system 760 and heat spreader 755 to exhaust 785.

In some embodiments, the series of inlets 705 have an aggregate cross-sectional area of 10 mm² or more. For example, such a configuration is shown to have a flow loss of 4% across the filtration system (e.g., across the coarse filter) installed therein. In some embodiments, the series of inlets 705 have an aggregate cross-sectional area of 25 mm² or more. For example, such a configuration is shown to have a flow loss of less than 2% across the filtration system (e.g., across the coarse filter) when the aggregate cross-sectional area is 25 mm². In some embodiments, an inlet in the series of inlets 705 may have a cross sectional area of 3 mm². For example, each inlet may have dimensions of 1 mm×3 mm.

By combining external coarse filtration at a device protrusion (such as a camera bump) with an internally positioned fine filter encapsulating the cooling system inlet, this arrangement addresses the significant design challenges posed by thin, compact electronic devices. The two-stage filtration approach effectively manages particulate contamination and liquid ingress, while maintaining device aesthetic integrity and minimal internal footprint. As a result, cooling efficiency and reliability of the electronic device and its internal cooling system are substantially improved, extending operational life and ensuring sustained high performance.

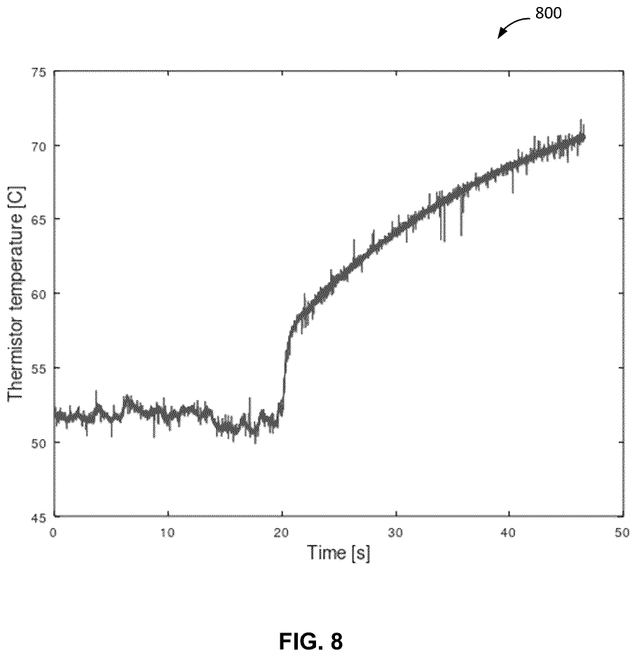

FIG. 8 depicts a response time for modulating a MEMS cooling system in response to an impulse in a thermal environment of a MEMS cooling system according to various embodiments.

According to various embodiments, a MEMS cooling system includes a cooling element (or actuator) that is driven to undergo vibrational motion. The vibrational motion drives a fluid that is used to cool one or more heat generating structures. At least one temperature sensor is mounted on the MEMS cooling system. In some embodiments, the temperature sensor(s) are mounted on the cooling element (e.g. at or near a flex connector that provides electrical connection to the cooling element).

In some embodiments, a temperature sensor is a thermistor. The thermistor may be used to control the MEMS cooling system. For example, the thermistor(s) may be used to activate/deactivate the MEMS cooling cell. Stated differently, the temperature of the cooling element(s) may be used to determine whether to activate and/or deactivate the MEMS cooling system. For example, the MEMS cooling system may be activated when the thermistor indicates the temperature of a cooling element is at least 60 degrees Celsius. The MEMS cooling system may be deactivated in response to the temperature of the cooling element dropping to not less than 50 degrees Celsius. The temperature sensor may also be used to control the flow rate of the fluid driven by the cooling cell, to control the power applied to the cooling cell (and thus, e.g., the amplitude of vibration of the cooling element), to control the frequency of vibration and/or temperature of the cooling element, and/or for other purposes. For example, the power to the cooling element may be controlled to maintain a particular temperature of the cooling element sensed by the thermistor. Because structural resonance of a cooling element depends on its temperature, controlling the power to the actuator to maintain a particular temperature may better allow the MEMS cooling system to maintain the vibrational motion of the cooling element(s) at or near resonance. In some embodiments, power to the cooling element(s) is controlled to achieve a minimum cooling element (thermistor) temperature for a given temperature of the heat-generating structure. This may obtain a maximum or close to maximum flow rate. Consequently, performance of the cooling system, as well as the device in which the cooling system is used, may be improved.

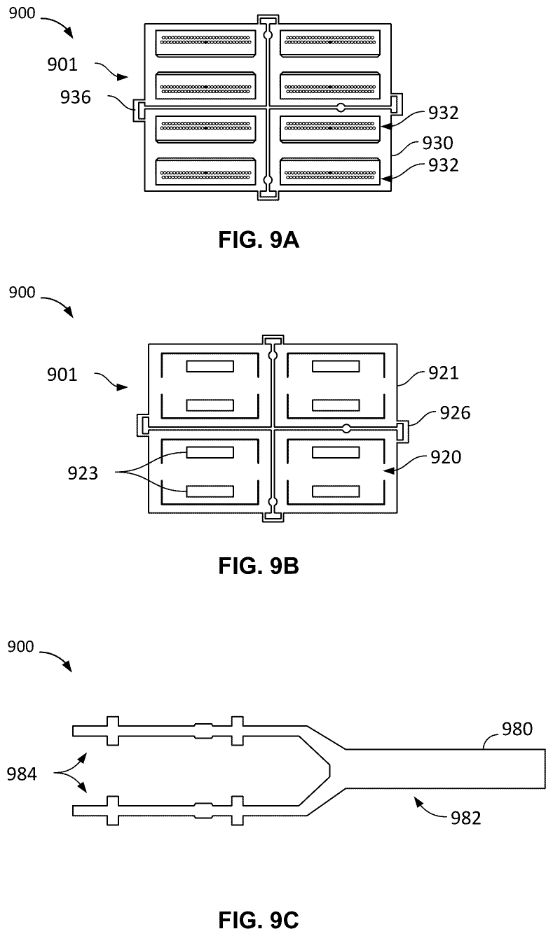

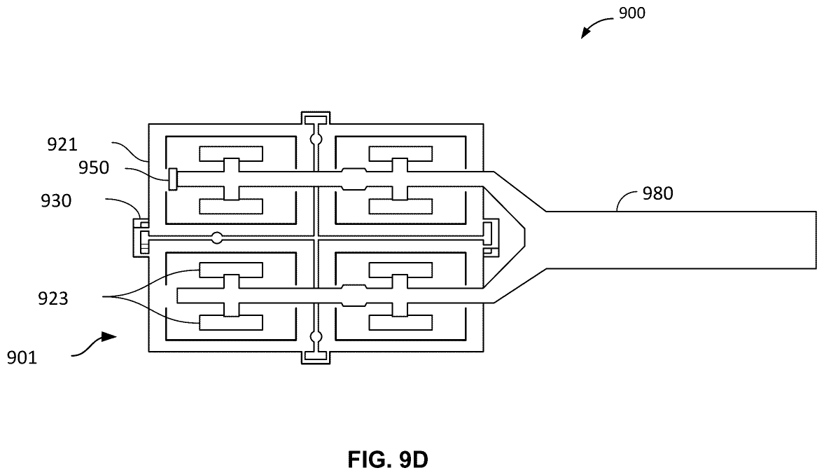

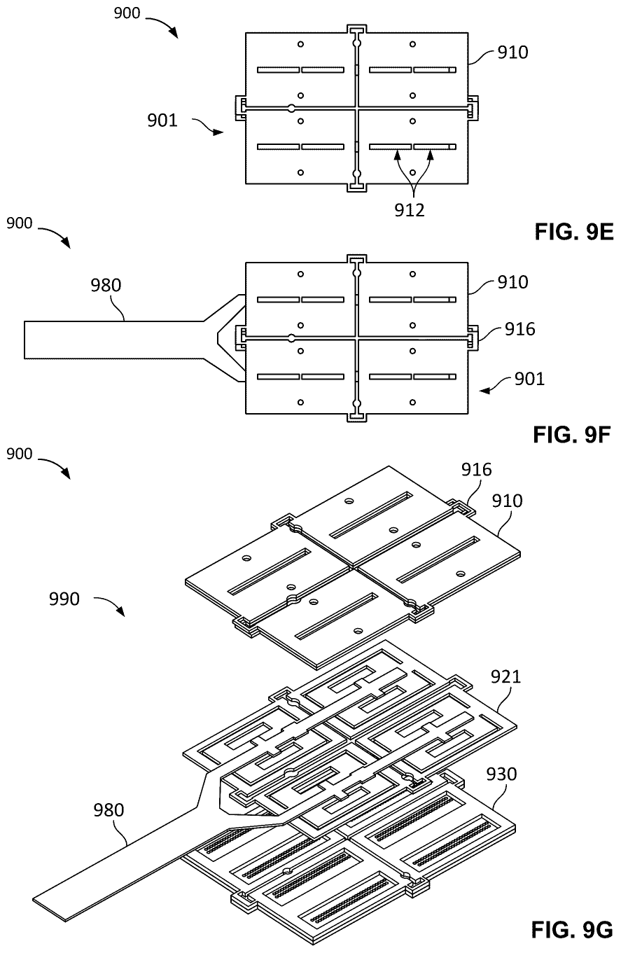

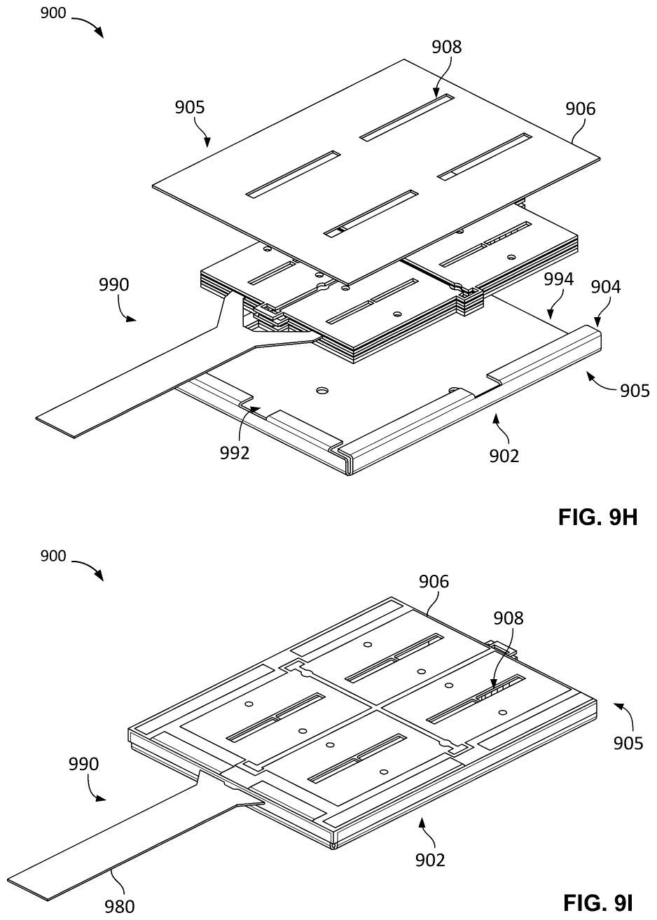

FIGS. 9A-9I depict an embodiment of system, or module, 900 during fabrication. FIGS. 9A-9I are not to scale. Cooling system 900 includes four cooling cells 901 of which one is labeled. Although four cooling cells 901 in a 2×2 configuration are shown, in some embodiments another number and/or another configuration of cooling cells 901 might be employed. Cells 901 are analogous to one or more of cooling cells described herein (e.g. cooling cell(s) 100, 200, and/or 300). FIG. 9A depicts a plan view of orifice plate 930 including orifices 932 therein. In some embodiments, orifice plate 930 is part of a sheet or other structure including multiple orifice plates 930. Although not labeled, orifice plate 930 includes tabs at the sides, outside the footprint of the cooling system 900 or cooling cells 901. FIG. 9B depicts a plan view of cooling system 900 after active element plate 921 has been added to orifice plate 930 (not shown in FIG. 9B). In some embodiments, active element plate 910 (as shown in FIGS. 9F and 9G) is part of a sheet or other structure including multiple active element plates 910. Thus, cooling elements 920 are shown. Anchors (not shown in FIG. 9B) may be formed on the opposing surface of active element plate 921, on the surface shown of orifice plate 930, or may be formed by an epoxy or other material used to attach orifice plate 930 and active element plate 921. Tabs are also present but unlabeled on active element plate 921. Also depicted in FIG. 9B are piezoelectric structures 923. Piezoelectric structures 923 are used to drive vibrational motion of cooling elements 920. In some embodiments, another mechanism for driving cooling elements 920 may be used.

FIG. 9C depicts electrical connector 980, which may be a flex connector. Tile portion 982 and cell portion 984 are indicated. FIG. 9D depicts cooling system 900 after connector 980 has been attached to active element plate 921. More specifically, connection has been made between electrical connector 980 and piezoelectric structures 923. If multiple tiles are being fabricated, then electrical connector 980 may be provided for each tile.

Various embodiments provide a cooling system that integrates (e.g., comprises) a thermistor or other temperature-sensitive element directly with a cooling structure (e.g., a cooling element) to actively measure and control the cooling system's operating temperature. The thermistor measures the temperature associated with the cooling element or another component closely thermally coupled to the cooling system, thereby providing an accurate and near-instantaneous proxy for the actual operating temperature. By continuously monitoring this temperature, the cooling system can rapidly modulate its cooling action, such as by adjusting power input, vibration amplitude, or airflow rate, in response to changes detected by the thermistor.

In some embodiments, the thermistor-based sensing technique enables the system to implement highly responsive temperature management, for example, because thermistors typically have rapid response times (e.g., on the order of milliseconds to tens of milliseconds). This rapid feedback capability enables the cooling system to dynamically adjust its actuation to maintain the cooling element's operating temperature at or near a predefined, constant value, or within a narrow and optimal temperature range. For example, if the thermistor detects a slight rise in temperature indicating increased thermal load, the cooling system can immediately respond by increasing its cooling performance (e.g., by enhancing actuator amplitude or increasing airflow) to restore the operating temperature to the desired setpoint (e.g., the optimal/ideal operating temperature or narrow range).

According to various embodiments, because the thermistor provides rapid and direct temperature feedback, the cooling system does not require the intervention or control of an external processor, computer, or dedicated controller. Instead, the cooling system itself can utilize simple analog or dedicated circuitry to achieve responsive, autonomous thermal management. This characteristic makes the cooling system (e.g., a cooling system implementing this thermistor-based sensing technique) ideal for applications in which computational resources or a separate controller are unavailable, impractical, or undesirable. For example, this self-contained temperature regulation approach may be especially advantageous in devices such as wearables, compact IoT sensors, or other electronic applications with strict size, power, or complexity constraints.

Moreover, maintaining the cooling system's operating temperature constant or within a narrow temperature range ensures optimal performance by consistently operating the cooling element near its resonant frequency. Because structural resonance is temperature-dependent, stabilizing the operating temperature allows the cooling system to remain in resonance, maximizing cooling efficiency and reducing energy consumption. Consequently, various embodiments implementing this thermistor-based, processor-free control technique enhances the device's operational reliability, thermal performance, and longevity.

According to various embodiments, one or more thermistors (or other temperature sensor(s)) are embedded into a module to allow real-time tracking of the thermal state the cooling system (e.g., a system comprising four cooling cells in a 2×2 array) or other MEMS cooling system. In the example shown, cooling system 900 comprises thermistor 950 disposed on or near the electrical connector. In other implementations, cooling system 900 may additionally, or alternatively, comprise a thermistor(s) on or within close proximity to a piezoelectric structures of the piezoelectric structures 923.

In some embodiments, the temperature sensor(s) (e.g., the thermistor(s)) measure the temperature(s) of the cooling element(s) (or a temperature of a region or component that can serve as a proxy for the temperature of the cooling element(s). In some embodiments, the temperature sensor(s) may be located on another part of the MEMS cooling system.

The thermistor may be configured to track/sense the thermal state of the carrier (e.g., the cooling element, often formed of titanium or stainless steel). For example, the thermistor is configured to detect the temperature of the piezoelectric actuator (e.g., a piezoelectric actuator of piezoelectric structures 923).

According to various embodiments, the ideal operating point of a cooling element is temperature-dependent. The fast thermal response (e.g., on the order of tens or hundreds of ms) of a thermistor allows for a quick detection and correction to the cooling element. For example, the system quickly detects the temperature change and can quickly control/actuate a vibrational motion of the cooling element(s). Accordingly, based on the temperature sensed by the thermistor(s), a MEMS cooling system may be controlled. For example, the MEMS cooling system may be turned on or off (e.g., activated/deactivated) based on temperature sensed by the thermistor(s).

In some embodiments, the power to the cooling element(s) may be controlled based on the temperature detected by the thermistor(s) or other temperature sensor disposed on or near the cooling element(s). For example, the system controls the amplitude of vibration of cooling element based on the detected temperature. The power for the cooling element may be controlled to obtain the minimum temperature for cooling element(s), which may provide the maximum flow.

In some embodiments, the power for a cooling element is controlled to ensure a constant temperature of the cooling element(s), which may allow the vibrational motion of the cooling element to be better maintained at resonance.

FIG. 9D depicts a plan view of an exposed portion of an embodiment of a MEMS cooling system. In the example shown, a thermistor 950 is provided at the end of a flex connector (e.g., electrical connector 980). The temperature of one cooling element is measured by thermistor 950. In other embodiments, multiple temperature sensors (e.g., multiple thermistors) are implemented, for example, to measure another cooling element(s) within the system.

When the cooling system (e.g., a MEMS cooling system) is not activated, the cooling element(s) are close to the temperature of the heat-generating structure(s) (e.g., a vapor chamber, integrated circuit, heat spreader, and/or other electrical component). For example, there may be a 1-2 degrees Celsius difference in temperature between the cooling element and the heat-generating structure(s). Generally, the temperature of the cooling element(s) is less than the temperature of the heat-generating structure(s) when the MEMS cooling system is activated because of the flow of cooler fluid (e.g., air) driven by the cooling element. Cooler air reaches the cooling element first so that will be cooled more than the heat generating structure. Thus, the thermistor temperature drops by more (e.g. 15-20 degrees Celsius-for example from 78 degrees-80 degrees Celsius to around 55-65 degrees) than the heating-generating structure temperature.

According to various embodiments, because the MEMS cooling system is controlled based on its own temperature (e.g., via thermistor-based temperature sensing), a separate controller (e.g., CPU, SoC in the device being cooled) may not be needed.

FIG. 9E depicts top plate 910 having vents 912 therein. Although a particular number and placement of vents 912 is shown, other configurations are possible. In some embodiments, top plate 910 is part of a sheet or other structure including multiple top plates 910. FIGS. 9F and 9G depict top and exploded views of cooling system 900 after top plate has been coupled to the remaining structures. If multiple tiles are formed from a sheet or other structure than individual tiles or desired configurations of tiles are separated from the sheet or other structure. For example, laser cutting may be performed. Subsequently, other structures, such as a heat spreader, may be attached to cooling system 900 to form a cooling module.

FIGS. 9H and 9I depict an embodiment of how fabrication of cooling system 900 is completed by adding hood 905. FIG. 9H depicts Tile 990 in conjunction with an exploded view of hood 905. Tile 990 is fit within fencing 904. Thus, tile 990 is aligned with heat spreader 902. Electrical connector 980 fits through aperture 992. Cover plate 906 is also aligned with tile 990. FIG. 9I depicts cooling system 900 after integration of module 900 has completed. Thus, cooling system 900 may be more readily assembled. Consequently, some or all of the benefits of the active cooling structures described may be achieved.

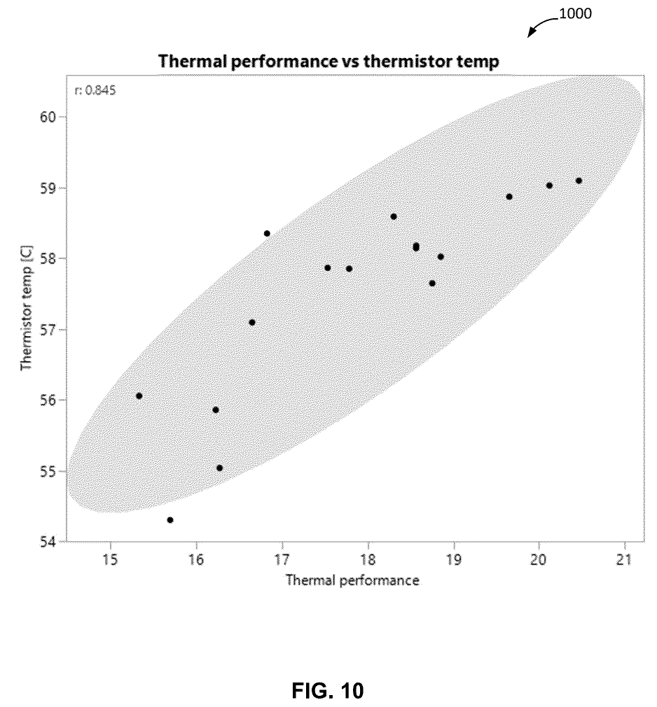

FIG. 10 depicts a relationship between temperature collected by a thermistor configured on a MEMS cooling system and thermal performance of a module associated with the MEMS cooling system.

In some embodiments, the system uses the temperature detected by the thermistor(s) (or other temperature sensors) in connection with controlling the system (e.g., toggling the cooling system on/off and/or controlling the power provided to a cooling element). For example, the system is configured to turn the cooling system on when the temperature detected by the thermistor reaches a first predefined temperature (e.g., when the temperature reaches 60° C.) and turns the cooling system off when the temperature detected by the thermistor reaches a second predefined temperature (e.g., when the temperature reaches 50° C.).

The system controls the power based on the temperature detected by the thermistor(s). For example, the system tunes the operating power applied to the cooling element (e.g., an air jet such as the AirJet provided by Frore Systems) based on the detected temperature. A higher thermistor temperature may imply that a lower power is applied to the cooling element. The system tunes the operating temperature to ensure that the operating temperature (e.g., the temperature detected by the thermistor) is constant (or within a predefined narrow temperature range). Maintaining the operating temperature constant ensures that the frequency of operation is maintained.

In some embodiments, the system tunes the power applied to the cooling element based on identifying (e.g., determining) a temperature change of the cooling element (e.g., the connector) and adjusts the frequency of operation of the cooling element (e.g., based on a predefined lookup table). The system can identify the local operation point of minimum thermistor temperature for maximizing flow (e.g., air flow).

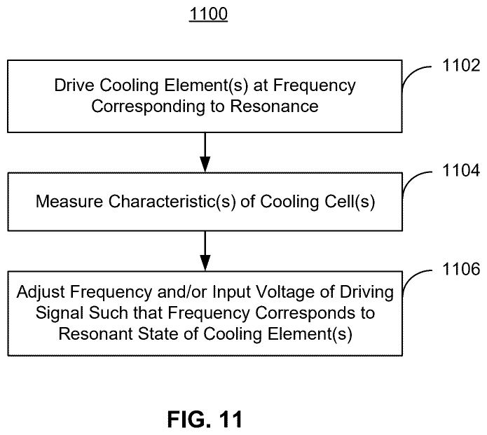

FIG. 11 depicts an embodiment of method 1100 for using an active cooling system. Method 1100 may include steps that are not depicted for simplicity. Method 1100 is described in the context of system 900. However, method 1100 may be used with other cooling systems including but not limited to systems and cells described herein.

A driving signal at a frequency and an input voltage corresponding to the resonant state of one or more cooling elements is provided to the active MEMS cooling system, at 1102. In some embodiments, a driving signal having the frequency corresponding to the resonant frequency of a specific cooling element is provided to that cooling element. In some embodiments, a driving signal is provided to multiple cooling elements. In such embodiments, the frequency of the driving signal corresponds to the resonant state of one or more cooling elements being driven, a statistical measure of the resonance, and/or within a threshold of the resonance as discussed above.

Characteristic(s) of the MEMS cooling system are monitored while the cooling element(s) are driven to provide a feedback signal corresponding to a proximity to a resonant state of the cooling element(s), at 1104. In some embodiments, characteristic(s) of each individual cooling element are monitored to determine the deviation of the frequency of vibration for that cooling element from the resonant frequency of that cooling element. In some embodiments, characteristic(s) for multiple cooling elements are monitored at 1104. The characteristic(s) monitored may be a proxy for resonance and/or a deviation therefrom. For example, the voltage at the cooling element, the power drawn by the cooling element, power output by the power source, peak-to-peak current output by the power source, peak voltage output by the power source, average current output by the power source, RMS current output by the power source, average voltage output by the power source, amplitude of displacement of the at least one cooling element, RMS current through the cooling element, peak voltage at the cooling element, average current through the cooling element, average voltage for at least one cooling element, and/or the peak current drawn by the cooling element may be monitored. Using the characteristic(s) monitored, a deviation from the resonant state of the cooling element (e.g. of the driving/vibration frequency the deviation from the resonant frequency) may be determined.

In some embodiments, the characteristic(s) measured for the cooling cell(s) includes an operating temperature, such as a temperature of a cooling element (or a component in close proximity to the cooling element that serves as a proxy for the cooling element temperature). The system may implement one or more thermistors (or other temperature sensors) to detect the operating temperature.

The frequency and/or input voltage is adjusted based on the feedback signal, at 1106. More specifically, 1106 includes updating the frequency and/or input voltage, based on the feedback signal, to correspond to resonant state(s) of the cooling element(s) at 1106. For example, the frequency for the drive signal may be updated to more closely match the resonant frequency/frequencies. In some embodiments, updating the frequency includes changing the frequency to correspond to a power drawn corresponding to the vibration of the cooling element(s) being maximized, a voltage provided at the cooling element(s) being maximized, a voltage across the cooling element(s) being minimized, and/or an amplitude of a current drawn by the at least one cooling element being minimized. In some embodiments, 1106 includes determining whether the feedback signal indicates that a drift in the resonant frequency of the cooling element(s) exceeds a threshold and identifying a new frequency in response to a determination that the drift exceeds the threshold. The new frequency accounts for the drift in the resonant frequency. The method also includes setting the new frequency as the frequency for the driving signal in response to the new frequency being identified.

In some embodiments, the frequency or input voltage for the cooling element is adjusted based at least in part on the temperature of the cooling element (e.g., the temperature detected by the thermistor). For example, the system controls the operation of (e.g., actuates the power provided to) the cooling element to maintain the operating temperature at a predefined temperature or within a predefined narrow temperature range.

For example, cooling element 120, 220, or 320 in MEMS cooling system 100, 200, or 300 is driven, at 1102. Thus, the cooling element 120, 220, 320 is driven at a frequency that is at or near resonance for one or more of the cooling elements. Characteristics of cooling element 120 or 320 within MEMS cooling system 100 or 300 are monitored, at 1104. Thus, the drift of the cooling element(s) 120 or 320 from resonance may be determined. Additionally, or alternatively, the drift of the operating temperature of the cooling element(s) 120 or 320 may be determined. The frequency or power applied to the cooling element may be adjusted based on the monitoring of 1104, at 1106. Thus, MEMS cooling system 100 or 300 may be kept at or near resonance.

Thus, using method 1100, an active cooling system, such as cooling system(s) 100, 200, 300, 400, and/or 500 may be efficiently driven. These cooling systems are also configured for improved alignment, symmetry, efficiency and/or reliability. Thus, method 1100 may be used to operate active MEMS cooling systems and achieve the benefits described herein.

Various examples of embodiments described herein are described in connection with flow diagrams. Although the examples may include certain steps performed in a particular order, according to various embodiments, various steps may be performed in various orders and/or various steps may be combined into a single step or in parallel.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system comprising:
a cooling structure comprising (i) one or more walls defining an inner chamber, (ii) a cooling element, and (iii) a filtration subsystem, wherein:
the one or more walls comprise one or more inlets, and one or more outlets;
the cooling element is configured to drive a fluid from the one or more inlets to the one or more outlets; and
the filtration subsystem comprises a coarse filter and a fine filter, and the filtration subsystem is configured to remove contaminants introduced by fluid flowing through the one or more inlets; and
a support structure thermally coupling the cooling structure to a heat-generating structure via thermal conduction.

2. The system of claim 1, wherein the cooling element comprises a first side and a second side opposite to the first side, and the cooling element is configured to undergo vibrational motion when actuated to drive the fluid from the first side to the second side.

3. The system of claim 1, wherein the filtration subsystem is configured to remove the contaminants from a fluid pathway across which the fluid flows, and the contaminants are removed from a point in the fluid pathway before a point at which the fluid pathway enters the cooling element.

4. The system of claim 1, wherein the coarse filter comprises a low-pressure drop coarse mesh filter.

5. The system of claim 1, wherein the coarse filter comprises a hydrophobic woven mesh.

6. The system of claim 1, wherein the fine filter comprises a filter having a minimum efficiency reporting value (MERV) of 14.

7. The system of claim 1, wherein the fine filter is configured to filter particles having a cross section of at least 0.3 microns.

8. The system of claim 1, wherein the filtration subsystem comprises a dust guard that is coupled to the cooling element.

9. The system of claim 8, wherein the dust guard comprises the fine filter and a manifold, and the fine filter and manifold are configured around the cooling element to define an inner chamber.

10. The system of claim 9, wherein the manifold is configured to seal the inner chamber to prevent the fluid from entering the inner chamber via the manifold.

11. The system of claim 9, wherein fluid is influx to the inner chamber defined by the dust guard via the fine filter.

12. The system of claim 1, wherein a pressure drop across the fine filter is greater than a pressure drop across the coarse filter.

13. The system of claim 1, wherein the fine filter and the coarse filter are configured to define a filter gap between the fine filter and the coarse filter.

14. The system of claim 13, wherein the filter gap is sufficiently large that a flow of the fluid through the fine filter reduces the fluid flow by less than or equal to 3.5 percent of a fluid flow without the fine filter and coarse filter being positioned in a fluid flow pathway.

15. The system of claim 13, wherein the filter gap is sufficiently large that a flow of the fluid through the fine filter reduces the fluid flow by less than or equal to 3.0 percent of a fluid flow without the fine filter and coarse filter being positioned in a fluid flow pathway.

16. The system of claim 13, wherein an average distance between an output surface of the coarse filter and an input surface of the fine filter is at least 200 microns.

17. The system of claim 13, wherein the cooling element is horizontally aligned with an output surface of the fine filter through which the fluid passes.

18. The system of claim 13, wherein the cooling element is horizontally displaced with respect to an output surface of the fine filter through which the fluid passes.

19. The system of claim 1, wherein the coarse filter is positioned at a wall of an air intake, and fluid flowing through the coarse filter flows through a dust guard before entering the cooling element.

20. A system comprising:
a cooling structure comprising a cooling element and a thermistor, wherein:
the cooling element is configured to cool a heat-generating structure via thermal conduction;
the thermistor is configured to measure a temperature associated with the cooling element; and
the cooling element is actuated based at least in part on the temperature; and
a support structure thermally coupling the cooling structure to the heat-generating structure via thermal conduction.
